(19) United States
(12) Patent Application Publication
(10) Pub. No.: US 2026/0293411 A1
(43) Pub. Date: Sep. 24, 2026

(54) ORGANIC MOLECULAR MEMORY

(71) Applicant: Kioxia Corporation, Tokyo (JP)

(72) Inventors: Kenji NAKAMURA, Yokohama Kanagawa (JP); Hideyuki NISHIZAWA, Toshima Tokyo (JP)

(21) Appl. No.: 19/319,671

(22) Filed: Sep. 4, 2025

(30) Foreign Application Priority Data
Mar. 21, 2025 (JP) 2025-046530

(51) Int. Cl. H10K 19/00; H10K 19/10; H10K 10/00

(52) U.S. Cl. CPC H10K 19/202; H10K 19/10; H10K 19/201; H10K 10/701

(57) ABSTRACT

An organic molecular memory includes a first electrode including a first part; a second electrode; a third electrode; an organic molecule layer provided between the first electrode and the second electrode, extending in a first direction from the first electrode toward the second electrode, and including a first molecule and a second molecule provided between the first molecule and the second electrode; and a conductive polymer, in which the first molecule is provided between the first part and the third electrode in a direction intersecting the first direction, and the conductive polymer is provided at a position between the first part and the first molecule or a position between the third electrode and the first molecule, or both.

### CROSS-REFERENCE TO RELATED APPLICATION(S)

This application is based upon and claims the benefit of priority from Japanese Patent Application No. 2025-046530, filed Mar. 21, 2025, the entire contents of which are incorporated herein by reference.

### FIELD

Embodiments described herein relate generally to an organic molecular memory.

### BACKGROUND

A micro-sized memory cell and a three-dimensional structure of a memory cell array having the micro-sized memory cell have been developed in order to implement a large capacity non-volatile memory device. Implementation of an even larger capacity non-volatile memory device is desired.

### BRIEF DESCRIPTION OF THE DRAWINGS

FIG. 1 is a block diagram of an organic molecular memory of a first embodiment.

FIG. 2 is an equivalent circuit diagram of a memory cell array of the organic molecular memory of the first embodiment.

FIG. 3 is a schematic cross-sectional view of the organic molecular memory of the first embodiment.

FIG. 4 is a diagram showing an example of a conductive polymer of the first embodiment.

FIGS. 5-9 are each a diagram showing an example of the conductive polymer of the first embodiment.

FIG. 10 is a schematic cross-sectional view showing an example of a manufacturing method of the organic molecular memory of the first embodiment.

FIGS. 11-15 are each a schematic cross-sectional view showing an example of the manufacturing method of the organic molecular memory of the first embodiment.

FIGS. 16-20 are each an explanatory diagram of an operation of the organic molecular memory of the first embodiment.

FIG. 21 is a schematic cross-sectional view of an organic molecular memory of a first comparative example.

FIG. 22 is a schematic cross-sectional view of an organic molecular memory of a second comparative example.

FIG. 23 is a schematic cross-sectional view of an organic molecular memory of a first modification example of the first embodiment.

FIG. 24 is a schematic cross-sectional view of an organic molecular memory of a second modification example of the first embodiment.

FIG. 25 is a schematic cross-sectional view of an organic molecular memory of a third modification example of the first embodiment.

FIG. 26 is a schematic cross-sectional view of an organic molecular memory of a fourth modification example of the first embodiment.

FIG. 27 is a schematic cross-sectional view of an organic molecular memory of a second embodiment.

FIGS. 28-31 are diagrams showing an example of an organic molecule of the second embodiment.

### DETAILED DESCRIPTION

Embodiments provide an organic molecular memory with a large storage capacity.

In general, according to one embodiment, an organic molecular memory includes a first electrode including a first part; a second electrode; a third electrode; an organic molecule layer provided between the first electrode and the second electrode, extending in a first direction from the first electrode toward the second electrode, and including a first molecule and a second molecule provided between the first molecule and the second electrode; and a conductive polymer, in which the first molecule is provided between the first part and the third electrode in a direction intersecting the first direction, and the conductive polymer is provided at a position between the first part and the first molecule or a position between the third electrode and the first molecule, or both.

Hereinafter, embodiments will be described with reference to the drawings. In the following description, the same reference numerals are given to the same or similar members, and the description of members that have already been described will be omitted as appropriate.

For example, secondary ion mass spectroscopy (SIMS), energy dispersive X-ray spectroscopy (EDX), X-ray diffraction (XRD), electron beam diffraction (EBD), X-ray photoelectron spectroscopy (XPS), synchrotron radiation X-ray absorption fine structure (XAFS), liquid chromatography, gas chromatography, or ion chromatography may be used to identify members of an organic molecular memory according to an embodiment. For example, a chemical bonding state between an organic molecule and a member of an organic molecular memory may be checked by using XPS.

For example, a transmission electron microscope (TEM) may be used to measure thicknesses of the members of the organic molecular memory according to the embodiment, a distance between the members, and the like.

For example, an atomic force microscope (AFM) or a scanning tunneling microscope (STM) may be used to identify a molecular structure of the organic molecule.

In the present specification, the term "chemical bond" is a concept indicating any of a covalent bond, an ionic bond, or a metallic bond, excluding a hydrogen bond and a van der Waals bond.

In the present specification, the term “facing” encompasses configurations in which another element is present between two elements facing each other.

### First Embodiment

An organic molecular memory of the first embodiment includes a first electrode including a first part; a second electrode; a third electrode; an organic molecule layer provided between the first electrode and the second electrode, extending in a first direction from the first electrode toward the second electrode, and including a first molecule and a second molecule provided between the first molecule and the second electrode; and a conductive polymer. The first molecule is provided between the first part and the third electrode in a direction intersecting the first direction, and the conductive polymer is provided at a position between the first part and the first molecule or a position between the third electrode and the first molecule, or both.

The organic molecular memory of the first embodiment is a non-volatile organic molecular memory 100 in which memory cells are three-dimensionally arranged. In the organic molecular memory 100, the memory cells store data using charges within organic molecules. The organic molecular memory 100 performs a shift register operation.

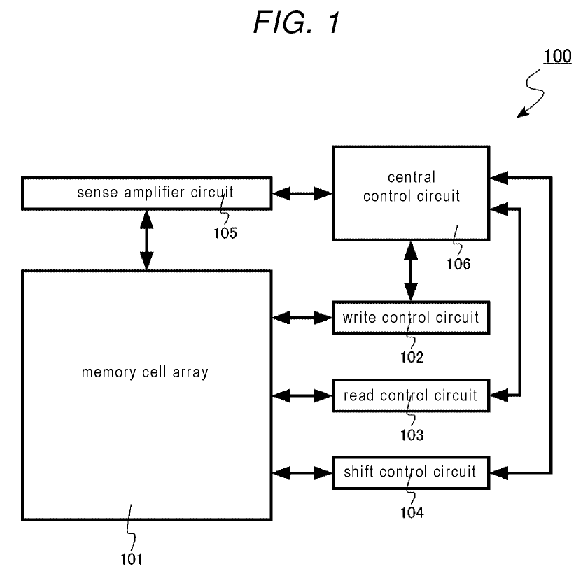

FIG. 1 is a block diagram of the organic molecular memory according to the first embodiment. As shown in FIG. 1, the organic molecular memory 100 includes a memory cell array 101, a write control circuit 102, a read control circuit 103, a shift control circuit 104, a sense amplifier circuit 105, and a central control circuit 106.

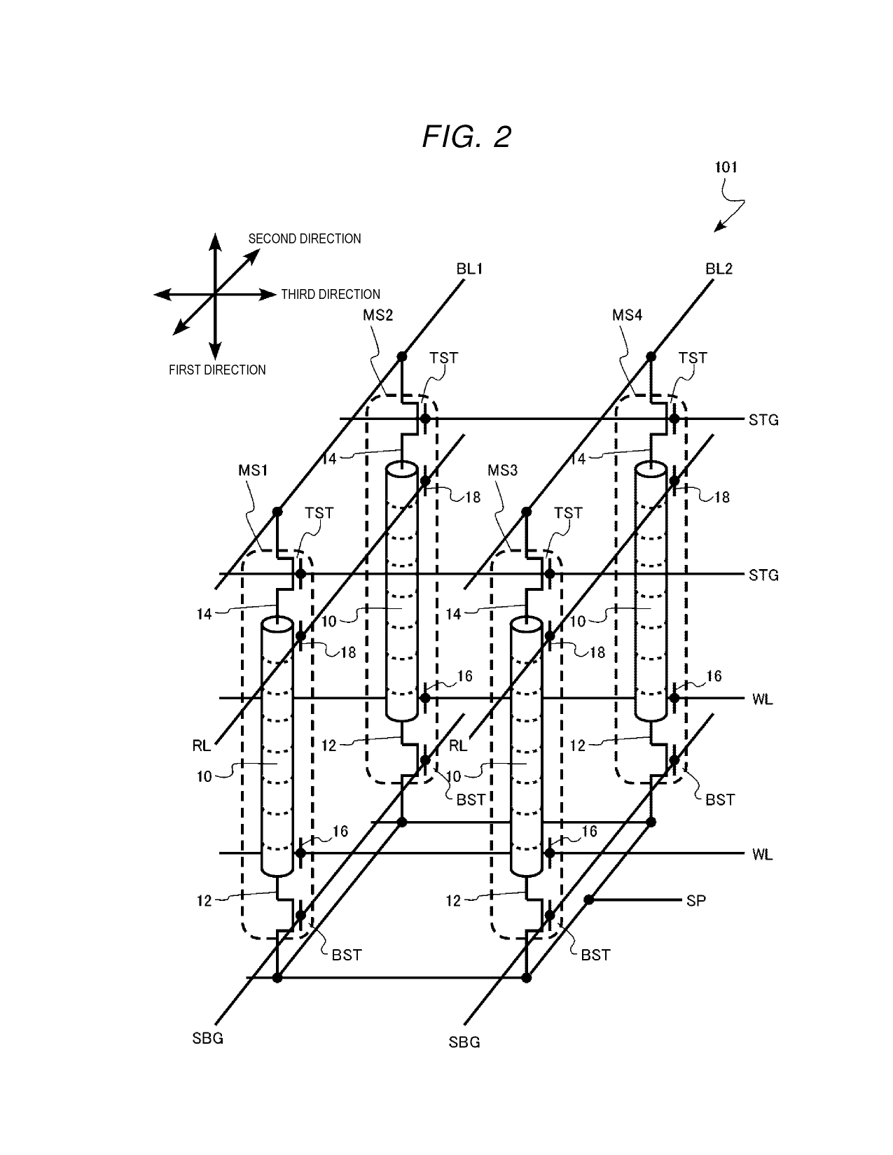

FIG. 2 is an equivalent circuit diagram of the memory cell array of the organic molecular memory of the first embodiment.

As shown in FIG. 2, the memory cell array 101 includes a first memory string MS1, a second memory string MS2, a third memory string MS3, a fourth memory string MS4, a source plate SP, a lower select gate line SBG, an upper select gate line STG, a write line WL, a read line RL, a first bit line BL1, and a second bit line BL2.

The first bit line BL1 is an example of a first wire. The second bit line BL2 is an example of a second wire.

Hereinafter, the first memory string MS1, the second memory string MS2, the third memory string MS3, and the fourth memory string MS4 may be individually or collectively referred to as the memory string MS. The first bit line BL1 and the second bit line BL2 may be individually or collectively referred to as the bit line BL.

Each of the first memory string MS1, the second memory string MS2, the third memory string MS3, and the fourth memory string MS4 includes an organic molecule layer 10, a lower electrode 12, an upper electrode 14, a write electrode 16, a read electrode 18, a lower select gate transistor BST, and an upper select gate transistor TST.

The lower electrode 12 is an example of a first electrode. The upper electrode 14 is an example of a second electrode. The write electrode 16 is an example of a third electrode. The read electrode 18 is an example of a fourth electrode.

In the memory cell array 101, a direction from the lower electrode 12 to the upper electrode 14 is defined as a first direction. A direction intersecting with the first direction is defined as a second direction. A direction intersecting with the first direction and the second direction is defined as a third direction. For example, the second direction is perpendicular to the first direction. For example, the third direction is perpendicular to the first direction and the second direction.

As shown in FIG. 2, the first memory string MS1, the second memory string MS2, the third memory string MS3, and the fourth memory string MS4 extend in the first direction.

The first bit line BL1 and the second bit line BL2 extend in the second direction. The first memory string MS1 and the second memory string MS2 are provided between the first bit line BL1 and the source plate SP. The third memory string MS3 and the fourth memory string MS4 are provided between the second bit line BL2 and the source plate SP.

The first bit line BL1 is provided in the first direction of the first memory string MS1 and the second memory string MS2. The first bit line BL1 is electrically connected to the first memory string MS1 and the second memory string MS2.

The second bit line BL2 is provided in the first direction of the third memory string MS3 and the fourth memory string MS4. The second bit line BL2 is electrically connected to the third memory string MS3 and the fourth memory string MS4. The second bit line BL2 is electrically separated from the first bit line BL1.

The organic molecule layer 10 includes a plurality of organic molecules. Each of the plurality of organic molecules functions as a memory cell.

The lower select gate transistor BST is provided between the lower electrode 12 and the source plate SP. The lower select gate line SBG extends in the second direction.

The lower select gate transistor BST is controlled to enter an ON state or an OFF state by a gate voltage applied to the lower select gate line SBG. The lower select gate transistor BST has a function of selecting a desired memory string MS from a plurality of memory strings MS. The lower select gate transistor BST may not be provided.

The upper select gate transistor TST is provided between the upper electrode 14 and the first bit line BL1 or between the upper electrode 14 and the second bit line BL2. The upper select gate line STG extends in the third direction.

The upper select gate transistor TST is controlled to enter an ON state or an OFF state by a gate voltage applied to the upper select gate line STG. The upper select gate transistor TST has a function of selecting the desired memory string MS from the plurality of memory strings MS.

One desired memory string MS may be selected by controlling the lower select gate transistor BST and the upper select gate transistor TST.

The write line WL extends in the third direction. The write line WL is connected to the write electrode 16. Data is written into the organic molecules facing the write electrode 16 by a write voltage applied to the write line WL.

For example, the write electrode 16 of the first memory string MS1 and the write electrode 16 of the third memory string MS3 are electrically connected to each other by the write line WL. For example, the write electrode 16 of the second memory string MS2 and the write electrode 16 of the fourth memory string MS4 are electrically connected to each other by the write line WL.

The read line RL extends in the second direction. The read line RL is connected to the read electrode 18. Data of the organic molecules facing the read electrode 18 is read by detecting a current flowing between the read electrode 18 and the upper electrode 14.

For example, the read electrode 18 of the first memory string MS1 and the read electrode 18 of the second memory string MS2 are electrically connected to each other by the read line RL. For example, the read electrode 18 of the third memory string MS3 and the read electrode 18 of the fourth memory string MS4 are electrically connected to each other by the read line RL.

For example, the write control circuit 102 has a function of selecting the write line WL and controlling a voltage to be applied to the selected write line WL.

For example, the read control circuit 103 has a function of selecting the read line RL and controlling a voltage to be applied to the selected read line RL.

The shift control circuit 104 has a function of controlling a shift register operation of the memory string MS. The shift control circuit 104 has a function of transmitting data stored in an organic molecule OM in the first direction by applying a shift voltage between the lower electrode 12 and the upper electrode 14 of the memory string MS.

The sense amplifier circuit 105 has a function of detecting the data stored in the organic molecule OM by amplifying a current flowing in the bit line BL or a voltage of the bit line BL.

The central control circuit 106 controls an operation of the organic molecular memory 100. The central control circuit 106 controls the write control circuit 102, the read control circuit 103, the shift control circuit 104, and the sense amplifier circuit 105.

For example, the write control circuit 102, the read control circuit 103, the shift control circuit 104, the sense amplifier circuit 105, and the central control circuit 106 are configured with transistors and wire layers formed on a semiconductor substrate (not shown).

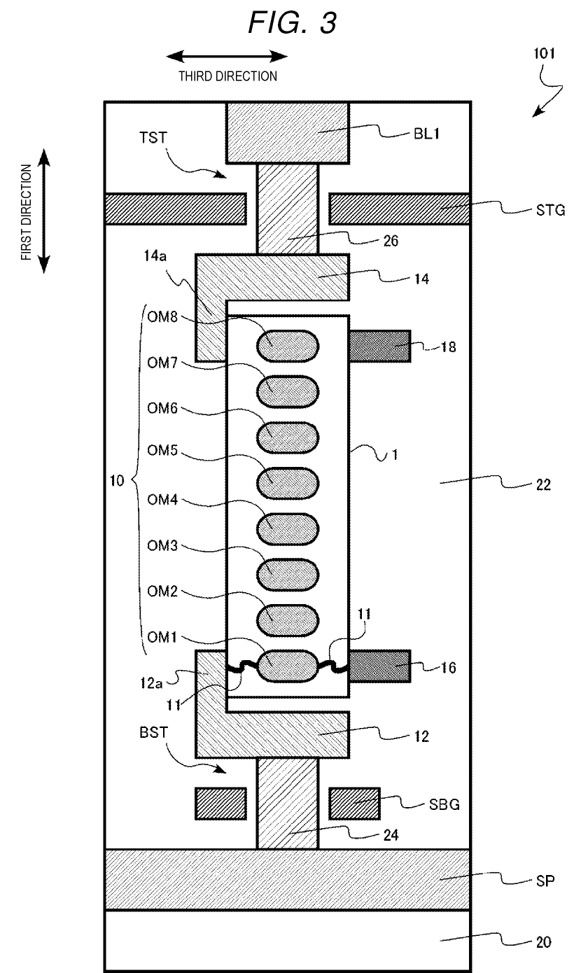

FIG. 3 is a schematic cross-sectional view of the organic molecular memory of the first embodiment. FIG. 3 is a cross-sectional view of the memory cell array 101. FIG. 3 is a cross-sectional view parallel to the first direction and the third direction. FIG. 3 is a cross section including the first memory string MS1.

The memory cell array 101 includes the organic molecule layer 10, a conductive polymer 11, the lower electrode 12, the upper electrode 14, the write electrode 16, the read electrode 18, a substrate insulating layer 20, an interlayer insulating layer 22, the source plate SP, the first bit line BL1, the lower select gate transistor BST, and the upper select gate transistor TST.

The lower electrode 12 is an example of a first electrode. The upper electrode 14 is an example of a second electrode. The write electrode 16 is an example of a third electrode. The read electrode 18 is an example of a fourth electrode.

The organic molecule layer 10 includes a first organic molecule OM1, a second organic molecule OM2, a third organic molecule OM3, a fourth organic molecule OM4, a fifth organic molecule OM5, a sixth organic molecule OM6, a seventh organic molecule OM7, and an eighth organic molecule OM8.

The first organic molecule OM1 is an example of the first molecule. The eighth organic molecule OM8 is an example of the second molecule. The second organic molecule OM2 is an example of the third molecule. The seventh organic molecule OM7 is an example of the fourth molecule.

Hereinafter, the first organic molecule OM1, the second organic molecule OM2, the third organic molecule OM3, the fourth organic molecule OM4, the fifth organic molecule OM5, the sixth organic molecule OM6, the seventh organic molecule OM7, and the eighth organic molecule OM8 may be individually or collectively referred to as the organic molecule OM.

The lower select gate transistor BST includes a first semiconductor layer 24. The upper select gate transistor TST includes a second semiconductor layer 26.

For example, the substrate insulating layer 20 is an oxide. For example, the substrate insulating layer 20 is a silicon oxide.

The source plate SP is provided on the substrate insulating layer 20. The source plate SP is a conductor. For example, the source plate SP is a metal or a semiconductor. For example, the source plate SP is tungsten.

The first semiconductor layer 24 is provided between the source plate SP and the lower electrode 12. For example, the first semiconductor layer 24 is in contact with the source plate SP and the lower electrode 12.

When the lower select gate transistor BST enters the ON state, a channel is formed in the first semiconductor layer 24. For example, the first semiconductor layer 24 is polycrystalline silicon.

A part of the source plate SP functions as a source and drain region of the lower select gate transistor BST. The lower electrode 12 functions as a source and drain region of the lower select gate transistor BST.

A part of the lower select gate line SBG functions as a gate electrode of the lower select gate transistor BST. A gate insulating film (not shown) is provided between a part of the lower select gate line SBG and the first semiconductor layer 24.

The lower select gate line SBG is a conductor. For example, the lower select gate line SBG is a metal. For example, the lower select gate line SBG is tungsten.

The lower electrode 12 is provided between the source plate SP and the organic molecule layer 10. The lower electrode 12 is provided between the first semiconductor layer 24 and the organic molecule layer 10. In the first direction, a dielectric layer is provided between the lower electrode 12 and the organic molecule layer 10. In the first direction, for example, a part of the interlayer insulating layer 22 is provided between the lower electrode 12 and the organic molecule layer 10.

The lower electrode includes a first part 12a. The first part 12a faces the first organic molecule OM1 in a direction intersecting with the first direction. For example, the first part 12a faces the first organic molecule OM1 in a direction orthogonal to the first direction. For example, the first part 12a faces the first organic molecule OM1 in the third direction.

The lower electrode 12 is a conductor. For example, the lower electrode 12 is a metal or a semiconductor. For example, the lower electrode 12 is tungsten.

The write electrode 16 faces the first organic molecule OM1 in a direction intersecting the first direction. For example, the write electrode 16 faces the first organic molecule OM1 in a direction orthogonal to the first direction. For example, the write electrode 16 faces the first organic molecule OM1 in the third direction. Alternatively, the write electrode 16 may be configured to face the first organic molecule OM1 in the second direction.

The write electrode 16 has a function of injecting charges into the first organic molecule OM1. For example, the write electrode 16 has a function of injecting electrons into the first organic molecule OM1.

For example, the write electrode 16 is electrically connected to the write line WL extending in the third direction, in a depth direction of the paper.

The write electrode 16 is a conductor. For example, the write electrode 16 is a metal or a semiconductor. For example, the write electrode 16 is tungsten.

The first organic molecule OM1 is provided between the first part 12a of the lower electrode 12 and the write electrode 16. For example, the first organic molecule OM1 is positioned between the first part 12a and the write electrode 16 in a direction intersecting with the first direction. For example, the first organic molecule OM1 is positioned between the first part 12a and the write electrode 16 in a direction orthogonal to the first direction. For example, the first organic molecule OM1 is positioned between the first part 12a and the write electrode 16 in the third direction. Alternatively, the first organic molecule OM1 may be positioned between the first part 12a and the write electrode 16 in the second direction.

For example, a distance between the first part 12a and the write electrode 16 is 2 times or more and 30 times or less a length of the first organic molecule OM1 in a direction from the first part 12a toward the write electrode 16. For example, a distance between the first part 12a and the write electrode 16 is 2 times or more and 30 times or less a length of the first organic molecule OM1 in the third direction.

For example, a distance between the first part 12a and the first organic molecule OM1 is larger than the length of the first organic molecule OM1 in the third direction. For example, a distance between the write electrode 16 and the first organic molecule OM1 is larger than the length of the first organic molecule OM1 in the third direction.

For example, the distance between the first part 12a and the first organic molecule OM1 is larger than a distance in the first direction between two organic molecules OM adjacent to each other in the first direction. For example, the distance between the write electrode 16 and the first organic molecule OM1 is larger than the distance in the first direction between the two organic molecules OM adjacent to each other in the first direction.

The conductive polymer 11 is provided between the first part 12a and the first organic molecule OM1. The conductive polymer 11 is provided between the write electrode 16 and the first organic molecule OM1.

For example, the conductive polymer 11 is chemically bonded to the first part 12a. For example, the conductive polymer 11 is chemically bonded to the write electrode 16. There is no chemical bond between the conductive polymer 11 and the first organic molecule OM1.

The conductive polymer 11 is a polymer having high electrical conductivity. The conductive polymer 11 has a function of reducing an electrical resistance between the first part 12a and the first organic molecule OM1. The conductive polymer 11 has a function of reducing the electrical resistance between the write electrode 16 and the first organic molecule OM1.

For example, the conductive polymer 11 is a polythiophene obtained by polymerizing a thiophene derivative, an oligothiophene obtained by polymerizing a thiophene derivative, a polypyrrole obtained by polymerizing a pyrrole derivative, an oligopyrrole obtained by polymerizing a pyrrole derivative, a polyisothianaphthene obtained by polymerizing an isothianaphthene derivative, an oligoisothianaphthene obtained by polymerizing an isothianaphthene derivative, a polyfuran obtained by polymerizing a furan derivative, an oligofuran obtained by polymerizing a furan derivative, a polyaniline obtained by polymerizing an aniline derivative, an oligoaniline obtained by polymerizing an aniline derivative, a polyvinylcarbazole obtained by polymerizing a vinylcarbazole derivative, or an oligovinylcarbazole obtained by polymerizing a vinylcarbazole derivative.

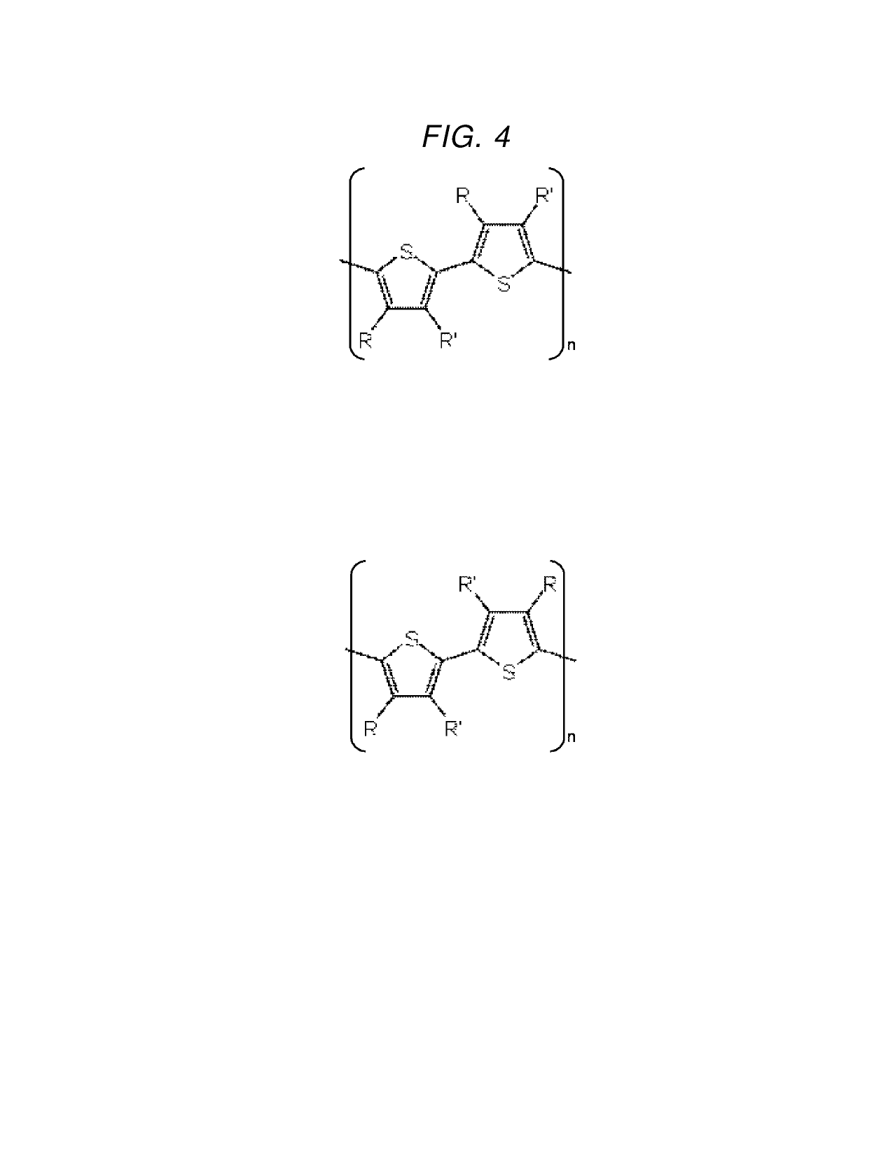

FIGS. 4, 5, 6, 7, 8, and 9 are diagrams showing examples of the conductive polymer of the first embodiment.

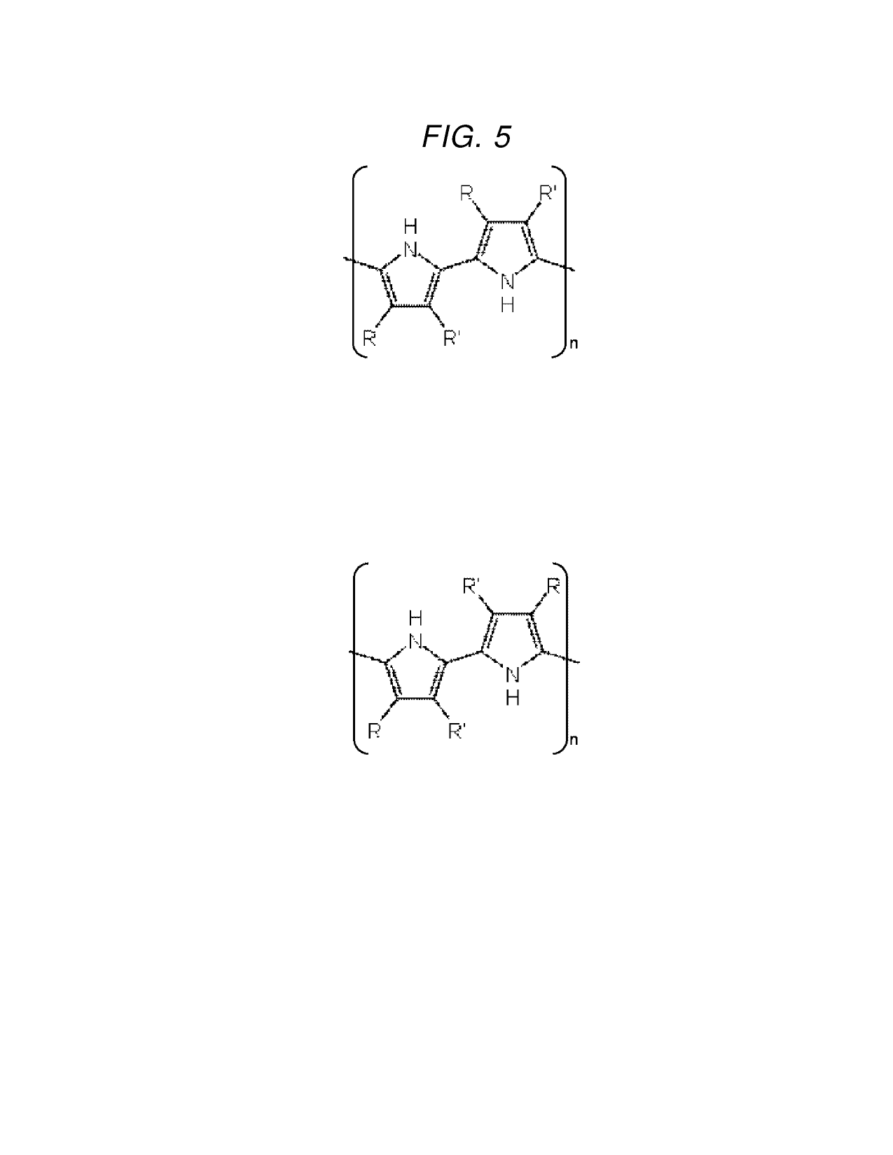

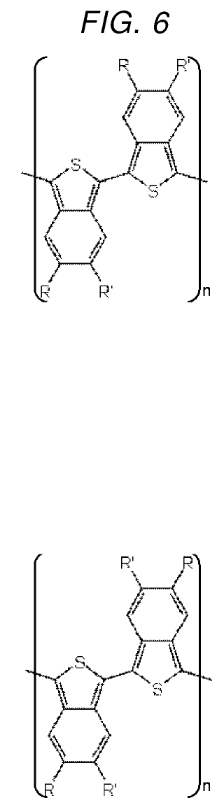

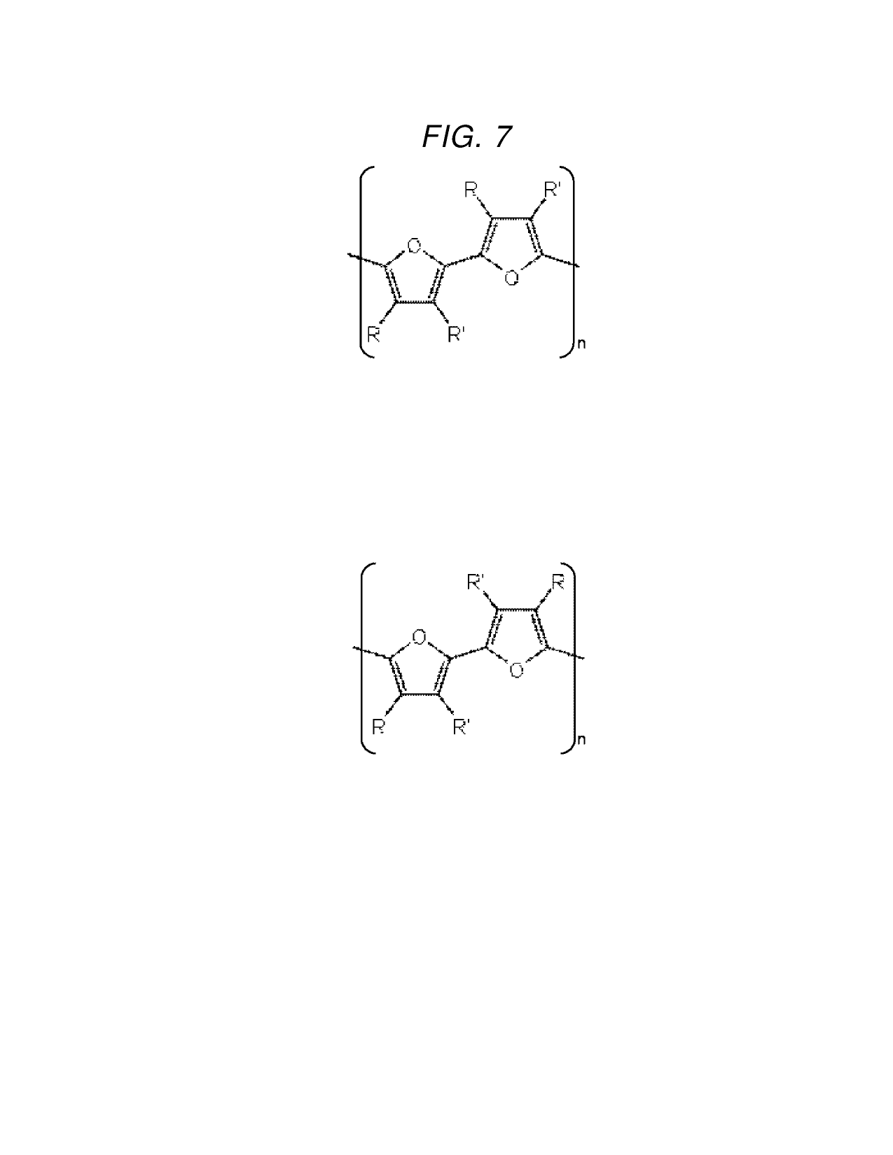

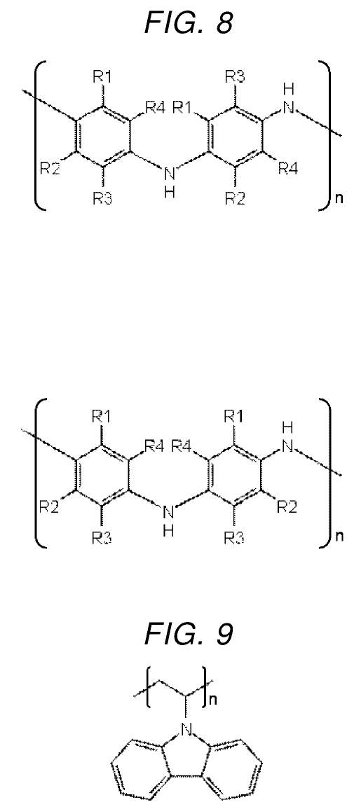

FIG. 4 is a structural formula of the polythiophene obtained by polymerizing the thiophene derivative, or the oligothiophene obtained by polymerizing the thiophene derivative. FIG. 5 is a structural formula of the polypyrrole obtained by polymerizing a pyrrole derivative or the oligopyrrole obtained by polymerizing the pyrrole derivative. FIG. 6 is a structural formula of the polyisothianaphthene obtained by polymerizing the isothianaphthene derivative or the oligoisothianaphthene obtained by polymerizing the isothianaphthene derivative. FIG. 7 is a structural formula of the polyfuran obtained by polymerizing the furan derivative or the oligofuran obtained by polymerizing the furan derivative. FIG. 8 is a structural formula of the polyaniline obtained by polymerizing the aniline derivative or the oligoaniline obtained by polymerizing the aniline derivative. FIG. 9 is a structural formula of the polyvinylcarbazole obtained by polymerizing the vinylcarbazole derivative or the oligovinylcarbazole obtained by polymerizing the vinylcarbazole derivative.

The organic molecule layer 10 is provided between the lower electrode 12 and the upper electrode 14. The organic molecule layer 10 extends in the first direction from the lower electrode 12 to the upper electrode 14. The organic molecule layer 10 is formed in a memory hole 1 provided in the interlayer insulating layer 22.

The first organic molecule OM1, the second organic molecule OM2, the third organic molecule OM3, the fourth organic molecule OM4, the fifth organic molecule OM5, the sixth organic molecule OM6, the seventh organic molecule OM7, and the eighth organic molecule OM8 are stacked in the first direction.

Chemical bonds are not present between two organic molecules OM adjacent to each other in the first direction. For example, covalent bonds are not present between two organic molecules OM adjacent to each other in the first direction.

For example, chemical bonds are not present between the first organic molecule OM1 and the second organic molecule OM2 adjacent to each other in the first direction. For example, covalent bonds are not present between the first organic molecule OM1 and the second organic molecule OM2.

For example, lengths of the organic molecule OM in the second direction and the third direction are 2 nm or more and 20 nm or less. For example, a disposition pitch of the organic molecules OM in the first direction is 1 nm or more and 5 nm or less.

For example, the lengths of the organic molecule OM in the second direction and the third direction are larger than a length of the organic molecule OM in the first direction.

For example, the organic molecule OM is a liquid crystal molecule. For example, the organic molecule OM includes a fullerene derivative.

The organic molecule OM may include a predetermined skeleton and a side chain radially arranged from the skeleton. The skeleton is referred to as a "central skeleton". For example, the side chain may include an alkyl group of a straight chain or a branched chain. For example, the organic molecule OM is a cyclic compound which has the central skeleton containing a metal element. The metal element is included as a metal ion and is in a state of being bonded in the organic molecule OM by a coordination bond. For example, the cyclic compound is a metallocene, a porphyrin, or a phthalocyanine, and the metal element is one metal element selected from a group consisting of iron (Fe), copper (Cu), cobalt (Co), titanium (Ti), nickel (Ni), zinc (Zn), and chromium (Cr).

In addition, the organic molecule OM is a cyclic compound which has the central skeleton containing a metal element, and for example, the cyclic compound is a naphthalocyanine, an anthrocyanine, a tetralocyanine, or a pentlocyanine, and the metal element is one metal element selected from a group consisting of manganese (Mn), iron (Fe), cobalt (Co), nickel (Ni), copper (Cu), and zinc (Zn).

For example, the organic molecule OM includes a double-decker complex including a side chain. The double-decker complex is a metal complex having a structure in which two planar molecules are stacked on each other. For example, the organic molecule OM is configured such that two phthalocyanine skeletons are stacked on each other and includes one rare earth element selected from a group consisting of lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), and lutetium (Lu). For example, in the organic molecule OM, the rare earth element is interposed between the two phthalocyanine skeletons.

In a case where the organic molecule OM of the first embodiment has the central skeleton of the cyclic compound containing a metal element, for example, each organic molecule OM has a cyclic structure in which constituent atoms form a plane. For example, the plane formed by the constituent atoms of the cyclic structure of the organic molecule OM intersects with the first direction. For example, the planes formed by the constituent atoms of the cyclic structures of two organic molecules OM disposed adjacent to each other face each other in the first direction.

In addition, in a case where the organic molecule OM of the first embodiment has the central skeleton of the cyclic compound containing the metal element, the direction in which the two metal elements contained in each of the two organic molecules OM arranged adjacent to each other are connected is a direction along the first direction. For example, the direction in which the metal elements of two organic molecules OM arranged adjacent to each other are connected is the first direction.

The upper electrode 14 is provided on the organic molecule layer 10. The upper electrode 14 is provided between the organic molecule layer 10 and the first bit line BL1. The organic molecule layer 10 is provided between the lower electrode 12 and the upper electrode 14.

The upper electrode 14 includes a second part 14a. The second part 14a faces the eighth organic molecule OM8 in a direction intersecting with the first direction. For example, the second part 14a faces the eighth organic molecule OM8 in a direction orthogonal to the first direction. For example, the second part 14a faces the eighth organic molecule OM8 in the third direction.

The upper electrode 14 is a conductor. For example, the upper electrode 14 is a metal or a semiconductor. For example, the upper electrode 14 is tungsten.

For example, the read electrode 18 faces the eighth organic molecule OM8 in a direction intersecting with the first direction. For example, the read electrode 18 faces the eighth organic molecule OM8 in a direction orthogonal to the first direction. For example, the read electrode 18 faces the eighth organic molecule OM8 in the third direction. Alternatively, the read electrode 18 may be configured to face the eighth organic molecule OM8 in the second direction.

The read electrode 18 has a function of causing a current to flow through the eighth organic molecule OM8. The read electrode 18 as one terminal and the upper electrode 14 as the other terminal cause the current to flow through the eighth organic molecule OM8.

For example, the read electrode 18 extends in a depth direction of the paper, that is, the second direction.

The read electrode 18 is a conductor. For example, the read electrode 18 is a metal or a semiconductor. For example, the read electrode 18 is tungsten.

The eighth organic molecule OM8 is provided between the second part 14a of the upper electrode 14 and the read electrode 18. For example, the eighth organic molecule OM8 is positioned between the second part 14a and the read electrode 18 in a direction intersecting with the first direction. For example, the eighth organic molecule OM8 is positioned between the second part 14a and the read electrode 18 in a direction orthogonal to the first direction. For example, the eighth organic molecule OM8 is positioned between the second part 14a and the read electrode 18 in the third direction. Alternatively, the eighth organic molecule OM8 may be positioned between the second part 14a and the read electrode 18 in the second direction.

For example, a distance between the second part 14a and the eighth organic molecule OM8 is 2 times or more and 30 times or less a length of the eighth organic molecule OM8 in a direction from the second part 14a toward the read electrode 18. For example, a distance between the second part 14a and the read electrode 18 is 2 times or more and 30 times or less a length of the eighth organic molecule OM8 in the third direction.

For example, the distance between the second part 14a and the eighth organic molecule OM8 is larger than the length of the eighth organic molecule OM8 in the third direction. For example, a distance between the read electrode 18 and the eighth organic molecule OM8 is larger than the length of the eighth organic molecule OM8 in the third direction.

For example, the distance between the second part 14a and the eighth organic molecule OM8 is larger than a distance in the first direction between the two organic molecules OM adjacent to each other in the first direction. For example, the distance between the read electrode 18 and the eighth organic molecule OM8 is larger than the distance in the first direction between the two organic molecules OM adjacent to each other in the first direction.

The upper select gate transistor TST includes a second semiconductor layer 26. The second semiconductor layer 26 is provided between the upper electrode 14 and the first bit line BL1. For example, the second semiconductor layer 26 is in contact with the upper electrode 14 and the first bit line BL1.

When the upper select gate transistor TST enters the ON state, a channel is formed in the second semiconductor layer 26. For example, the second semiconductor layer 26 is polycrystalline silicon.

The upper electrode 14 functions as a source and drain region of the upper select gate transistor TST. A part of the first bit line BL1 functions as the source and drain region of the upper select gate transistor TST.

A part of the upper select gate line STG functions as a gate electrode of the upper select gate transistor TST. A gate insulating film (not shown) is provided between a part of the upper select gate line STG and the second semiconductor layer 26.

The upper select gate line STG is a conductor. For example, the upper select gate line STG is a metal. For example, the upper select gate line STG is tungsten.

The first bit line BL1 is a conductor. For example, the first bit line BL1 is a metal. For example, the first bit line BL1 is tungsten.

For example, the interlayer insulating layer 22 is an oxide. For example, the interlayer insulating layer 22 is a silicon oxide.

Next, an example of a manufacturing method of the organic molecular memory of the first embodiment will be described. Hereinafter, an example of a manufacturing method of the memory cell array 101 of the organic molecular memory 100 will be described.

In the manufacturing method of the organic molecular memory of the first embodiment, the conductive polymer is formed by using an electrochemical polymerization method.

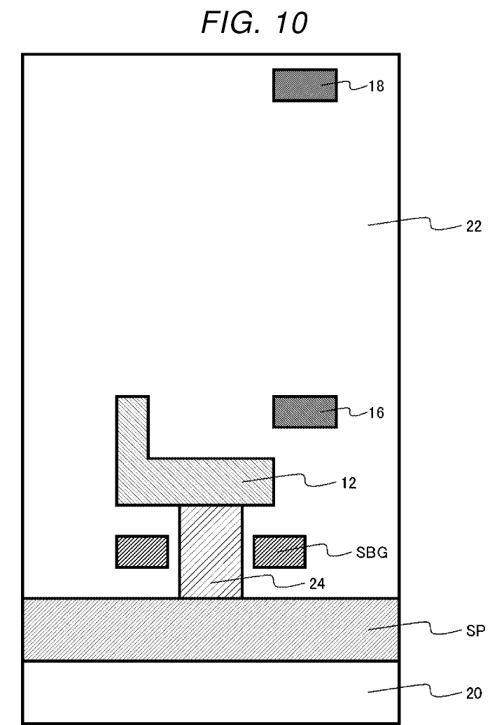

FIGS. 10, 11, 12, 13, 14, and 15 are schematic cross-sectional views showing examples of the manufacturing method of the organic molecular memory of the first embodiment. FIGS. 10 to 15 show cross sections corresponding to FIG. 3.

First, for example, the substrate insulating layer 20 is formed on a semiconductor substrate (not shown) using a known process technology. For example, the substrate insulating layer 20 is a silicon oxide layer. For example, the silicon oxide layer is formed by a chemical vapor deposition method (CVD method).

Next, the source plate SP, the lower select gate line SBG, the first semiconductor layer 24, the lower electrode 12, the write electrode 16, the read electrode 18, and the interlayer insulating layer 22 are formed on the substrate insulating layer 20 using a known process technology (FIG. 10). For example, the source plate SP, the lower select gate line SBG, the lower electrode 12, the write electrode 16, and the read electrode 18 are formed of tungsten. For example, the first semiconductor layer 24 is formed of polycrystalline silicon. For example, the interlayer insulating layer 22 is formed of silicon oxide.

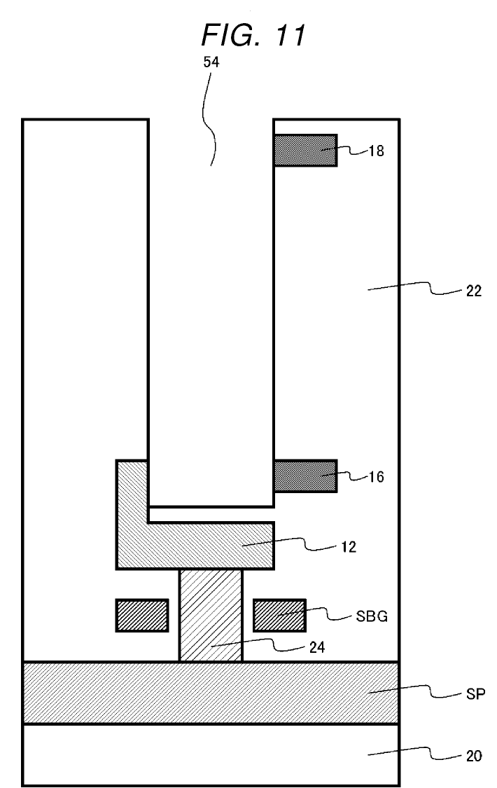

Next, an opening 54 is formed in the interlayer insulating layer 22 (FIG. 11). For example, the opening 54 is formed by a lithography method and a reactive ion etching method (RIE method). For example, a part of the interlayer insulating layer 22 is left on a bottom portion of the opening 54. The opening 54 becomes the memory hole 1.

Next, the opening 54 is filled with an electrolytic solution 56. A monomer is contained in the electrolytic solution.

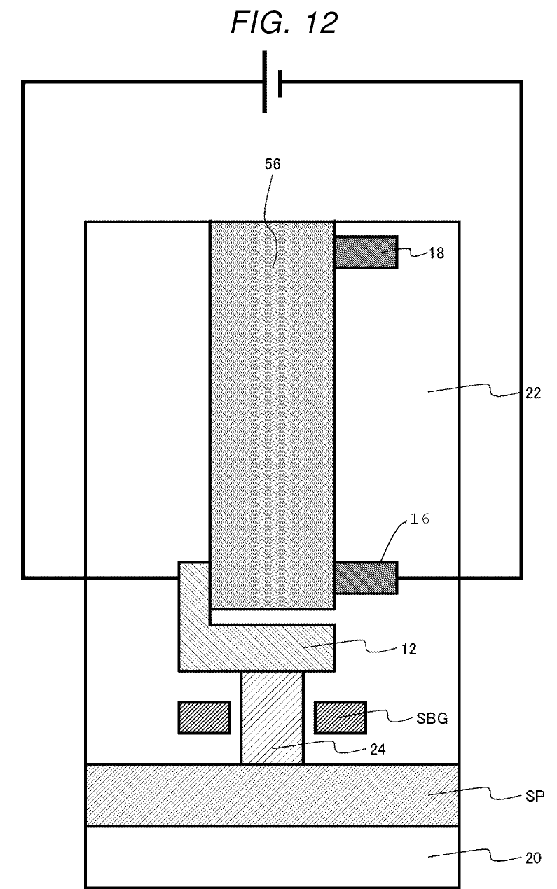

A voltage is applied between the lower electrode 12 and the write electrode 16 (FIG. 12). For example, a voltage is applied between an electrode pad (not shown) connected to the lower electrode 12 and an electrode pad (not shown) connected to the write electrode 16.

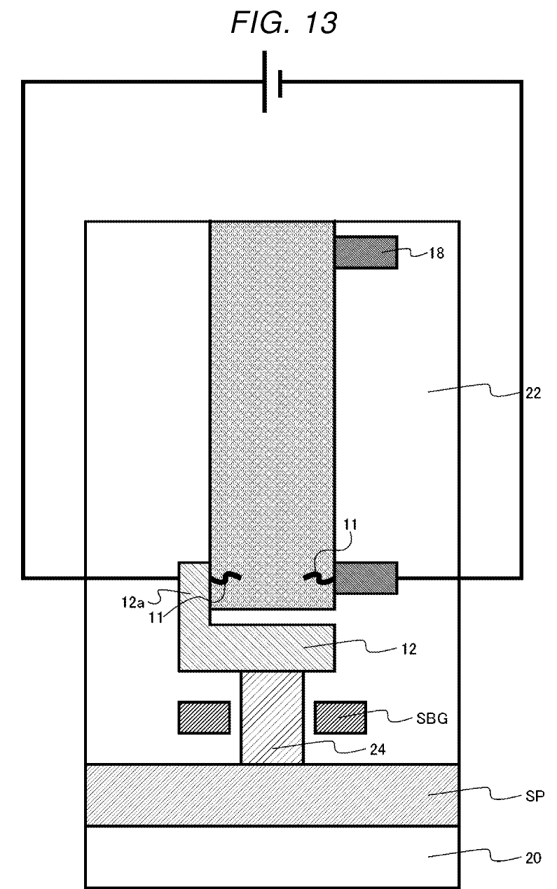

By the electrochemical polymerization, the bonded monomer is chemically bonded to the surface of the lower electrode 12 and the surface of the write electrode 16 (FIG. 13). The bonded monomer becomes the conductive polymer 11.

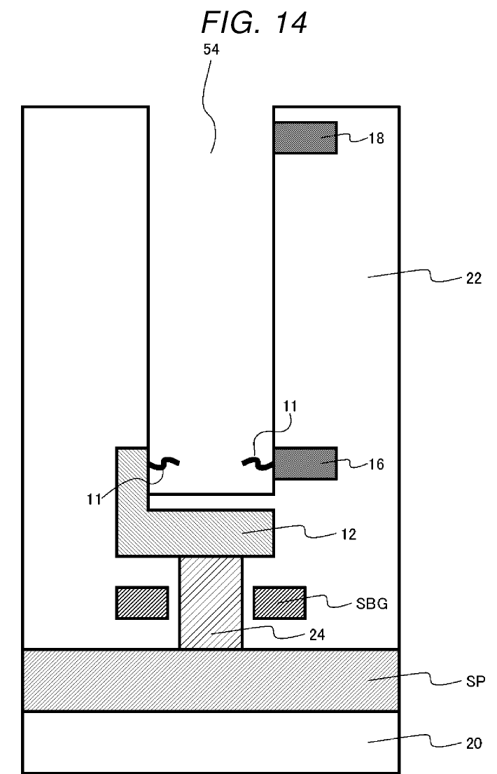

Next, the electrolytic solution 56 in the opening 54 is removed (FIG. 14).

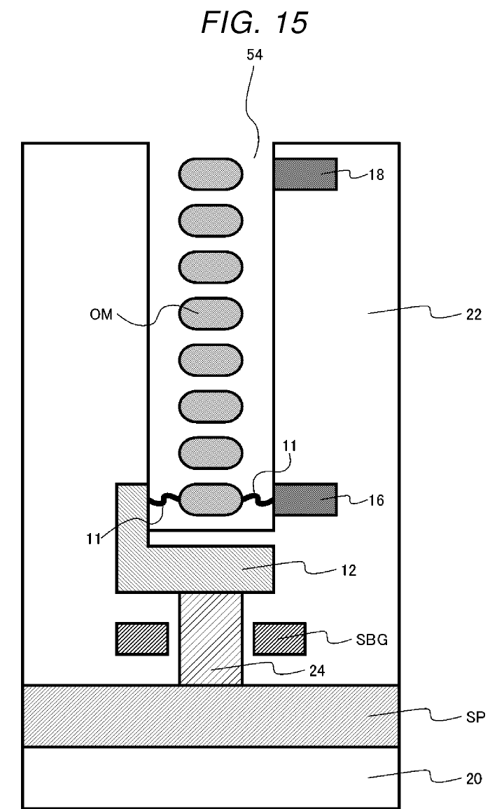

Next, a plurality of organic molecules OM are stacked in the opening 54 (FIG. 15). For example, the plurality of organic molecules OM are formed by an evaporation method. The plurality of organic molecules OM are arranged in a self-aligned manner in the first direction in the opening 54. In other words, the interaction between each organic molecule OM and its neighbor organic molecule OM causes the organic molecules OM to be aligned along the opening 54.

Thereafter, an insulating film is formed on the opening 54, and the upper electrode 14, the upper select gate line STG, the second semiconductor layer 26, and the first bit line BL1 are formed using a known process technology.

The memory cell array 101 of the organic molecular memory 100 of the first embodiment shown in FIG. 3 is manufactured by the manufacturing method described above.

Next, an operation of the organic molecular memory 100 will be described.

During a write operation and a read operation, the organic molecular memory 100 sequentially transmits data stored in a plurality of organic molecules OM stacked on each other in the organic molecule layer 10 to adjacent organic molecules OM. The organic molecular memory 100 performs a so-called shift register operation during the write operation and the read operation.

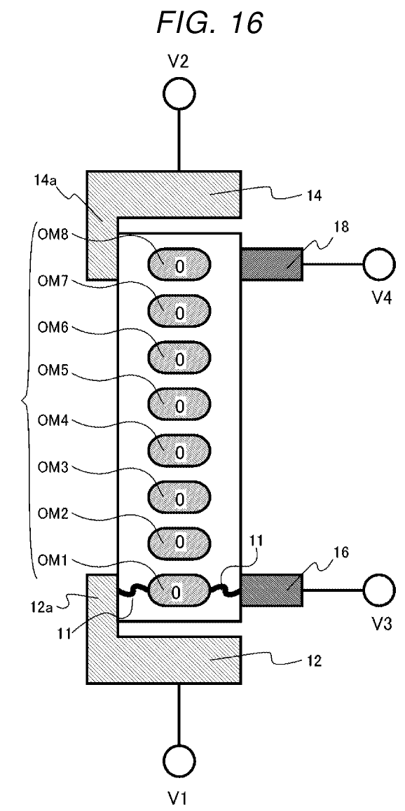

FIGS. 16, 17, 18, 19, and 20 are explanatory diagrams of the operation of the organic molecular memory of the first embodiment.

FIG. 16 shows an initial state of the operation of the organic molecular memory 100. In the operation of the organic molecular memory 100, a first voltage V1, a second voltage V2, a third voltage V3, and a fourth voltage V4 are applied to the lower electrode 12, the upper electrode 14, the write electrode 16, and the read electrode 18, respectively.

A state in which the electron is not written in the organic molecule OM is defined as data 0. Further, a state in which the electron is written in the organic molecule OM is defined as data 1.

As shown in FIG. 16, as the initial state of the operation of the organic molecular memory 100, data stored in all organic molecules OM is considered to be the data 0.

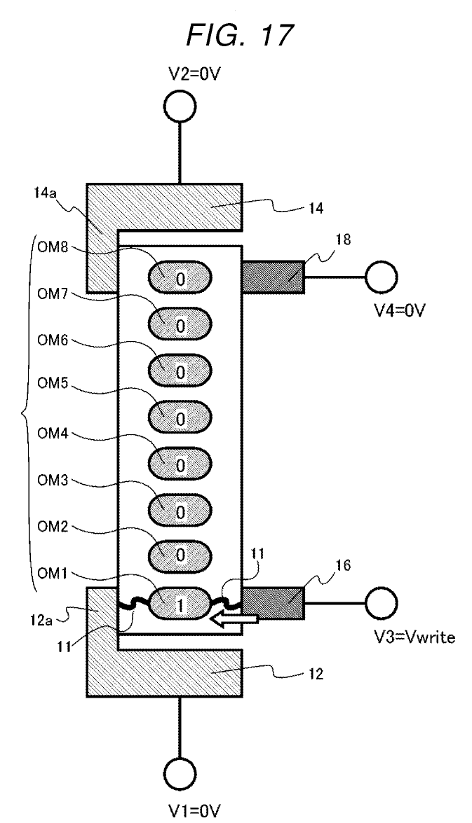

First, as shown in FIG. 17, for example, the data 1 is written into the first organic molecule OM1. In writing the data 1 into the first organic molecule OM1, the third voltage V3 is set to a voltage lower than the first voltage V1. For example, in writing the data 1 into the first organic molecule OM1, the first voltage V1 is set to 0 V, and the third voltage V3 is set to a write voltage Vwrite. The write voltage Vwrite is a negative voltage.

The electron is injected into the first organic molecule OM1 through the conductive polymer 11 from the write electrode 16, and data 1 is written into the first organic molecule OM1. In other words, data 1 is written by a reduction of the first organic molecule OM1.

The organic molecular memory 100 controls data stored in the organic molecule OM by injecting electrons into the organic molecule OM or extracting electrons from the organic molecule OM. In other words, the organic molecular memory 100 controls the data stored in the organic molecule OM by using an oxidation-reduction action of the organic molecule OM.

For example, in writing the data 1 into the first organic molecule OM1, the second voltage V2 is 0 V, and the fourth voltage V4 is 0 V.

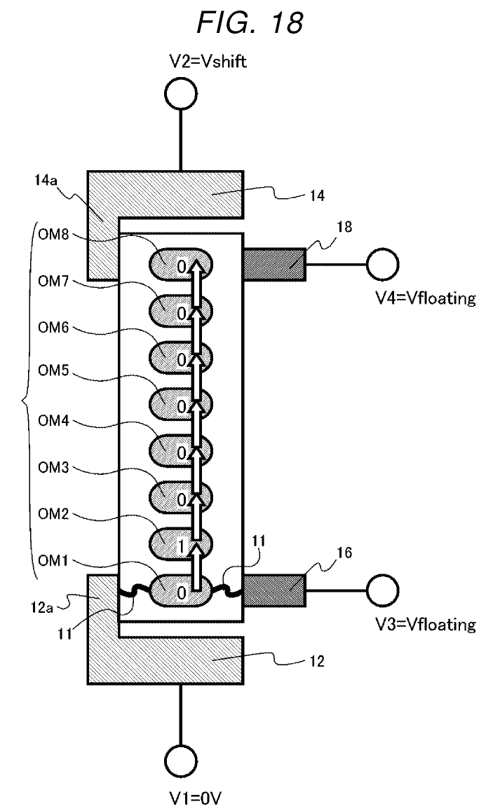

After the data 1 is written into the first organic molecule OM1, the data of the organic molecule OM is transmitted in a direction from the lower electrode 12 to the upper electrode 14 as shown in FIG. 18. For example, in transmitting the data of the organic molecule OM, the first voltage V1 is set to 0 V, and the second voltage V2 is set to a shift voltage Vshift. The shift voltage Vshift is a positive voltage. For example, the shift voltage Vshift is applied as a pulse.

For example, in transmitting the data of the organic molecule OM, the write electrode 16 and the read electrode 18 are set to floating potentials. Hereinafter, for convenience of description, a state in which the write electrode 16 and the read electrode 18 are set to the floating potentials will be referred to as a state in which the third voltage V3 and the fourth voltage V4 are floating voltages Vfloating.

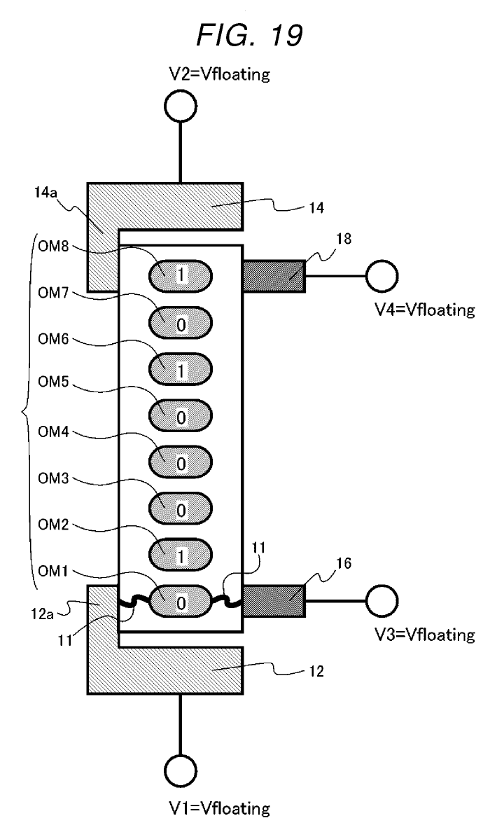

For example, by repeating writing of data into the first organic molecule OM1 and transmission of the data of the organic molecule OM, the data 0 or the data 1 is stored in all organic molecules OM as shown in FIG. 19. For example, the data stored in the organic molecule OM is stored by keeping the first voltage V1, the second voltage V2, the third voltage V3, and the fourth voltage V4 at the floating voltage Vfloating. In other words, the organic molecular memory 100 functions as a non-volatile memory capable of storing data even in a state in which a power supply voltage is not applied.

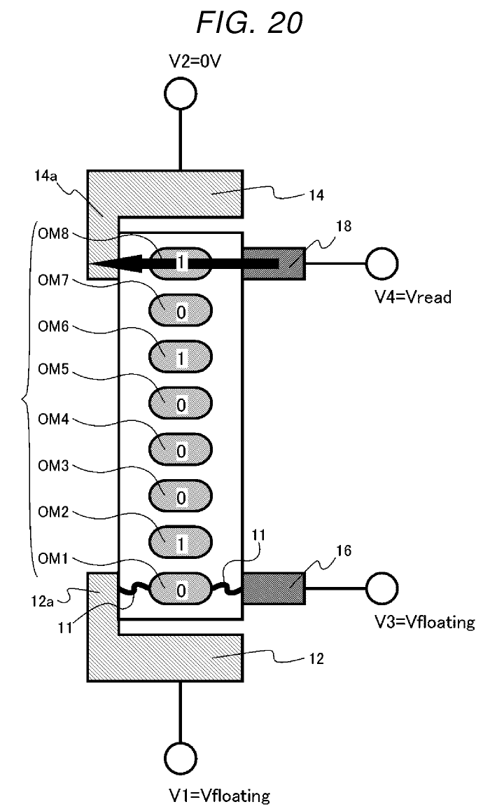

Next, as shown in FIG. 20, the data of the eighth organic molecule OM8 is read. For example, in reading the data of the eighth organic molecule OM8, the second voltage is set to 0 V, and the fourth voltage is set to a read voltage Vread. For example, the read voltage Vread is a positive voltage. For example, an absolute value of the read voltage Vread is smaller than an absolute value of the write voltage Vwrite.

A current flows from the read electrode 18 to the second part 14a of the upper electrode through the eighth organic molecule OM8. A level of the current flowing in the eighth organic molecule OM8 changes depending on the data stored in the eighth organic molecule OM8. For example, in a case where the data stored in the eighth organic molecule OM8 is the data 1, a large current flows as compared with a case where the data stored in the eighth organic molecule OM8 is the data 0. This is because the conductance of the eighth organic molecule OM8 changes due to the injection of the electron into the eighth organic molecule OM8.

For example, the current flowing from the read electrode 18 to the upper electrode 14 flows into the first bit line BL1 through the upper select gate transistor TST in the ON state. The data of the eighth organic molecule OM8 is read based on the current flowing in the first bit line BL1.

The organic molecular memory 100 reads the data stored in the organic molecule OM by detecting the current flowing from the read electrode 18 to the upper electrode 14. The current flowing from the read electrode 18 to the upper electrode 14 is a tunneling current through the wavefunction of the organic molecule OM.

For example, in reading the data of the eighth organic molecule OM8, the first voltage V1 and the third voltage V3 are the floating voltages Vfloating.

By repeating reading of the data of the eighth organic molecule OM8 and transmission of the data of the organic molecule OM, the data stored in all organic molecules OM of the organic molecule layer 10 may be read. After the data stored in all the organic molecules OM is read, the organic molecule layer 10 returns to the initial state.

Next, a mechanism of a data transmission operation of the organic molecular memory of the first embodiment will be described.

Each of the organic molecules OM of the first organic molecule OM1 to the eighth organic molecule OM8 has a highest occupied molecular orbital level (HOMO level), a first lowest unoccupied molecular orbital level (first LUMO level), and a second lowest unoccupied molecular orbital level (second LUMO level) as energy levels of the electron.

In a state in which the data 1 is stored in the organic molecule OM, one electron is present in the first LUMO level. In addition, in a state in which the data 0 is stored in the organic molecule OM, no electron is present in the first LUMO level.

When data is transmitted, the shift voltage Vshift is applied to the upper electrode 14 as the second voltage V2. The shift voltage Vshift is set to a voltage at which the energy levels of the first LUMO level and the second LUMO level match between the adjacent organic molecules OM.

Between the adjacent organic molecules OM, the energy level of the first LUMO level and the energy level of the second LUMO level match each other, so that the electron present in the first LUMO level may move to the second LUMO level of the adjacent organic molecules OM by a tunneling phenomenon. The electron that has moved to the second LUMO level moves to the first LUMO level and is stabilized after a certain time. In other words, the electron, which moves from the first LUMO level of the organic molecules OM to the second LUMO level of the organic molecules OM adjacent to each other, moves to the first LUMO level and is stabilized by energy dissipation from an excited state.

With the above mechanism, the data stored in the organic molecule OM is transmitted to the adjacent organic molecule OM. The data may be sequentially transmitted by applying the shift voltage Vshift as a pulse.

Next, an action and an effect of the organic molecular memory of the first embodiment will be described.

Implementation of a large capacity and low-cost non-volatile memory is desired. The organic molecular memory 100 according to the first embodiment uses an organic molecule as a memory cell. Use of a micro-sized organic molecule as a memory cell may achieve a micro-sized memory cell. The memory cell array 101 is provided with a three-dimensional structure by arranging the plurality of organic molecules OM in one direction in a self-aligned manner. For example, since the organic molecules OM are arranged in one direction to perform the shift register operation, a control electrode for controlling individual memory cells is not required. By providing the above configuration, the organic molecular memory 100 of the first embodiment may achieve large capacity and low cost of the organic molecular memory.

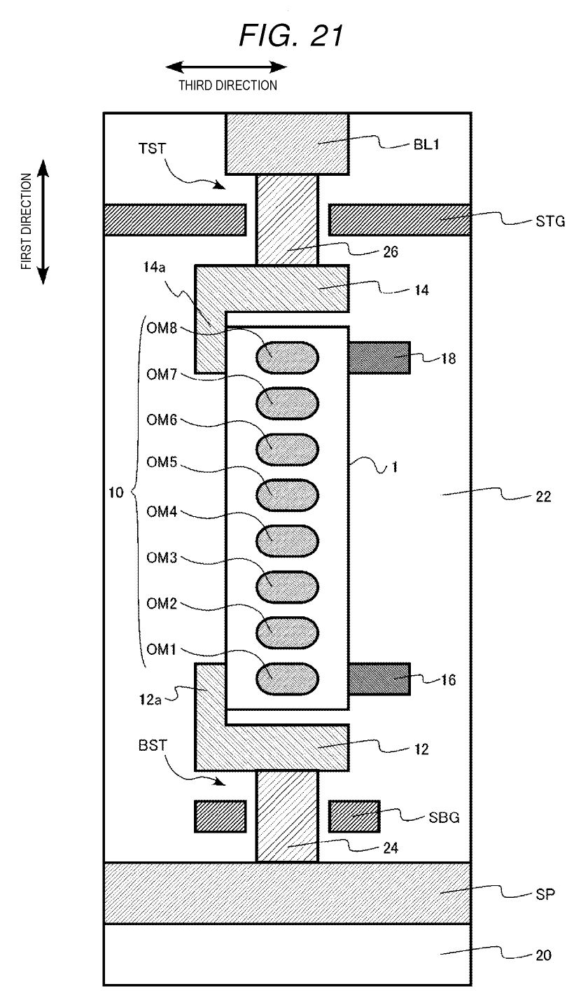

FIG. 21 is a schematic cross-sectional view of an organic molecular memory of a first comparative example. FIG. 21 is a cross-sectional view of the memory cell array. FIG. 21 is a view corresponding to FIG. 3 of the first embodiment.

The organic molecular memory of the first comparative example is different from the organic molecular memory 100 of the first embodiment in that the conductive polymer 11 is not provided.

In the organic molecular memory of the first comparative example, for example, a hole diameter of the memory hole 1 for forming the organic molecule layer 10 is two times or more the size of the organic molecule OM. For example, the organic molecular memory of the first comparative example has a distance between the first part 12a of the lower electrode 12 and the write electrode 16, which is two times or more the length of the first organic molecule OM1 in a direction from the first part 12a toward the write electrode 16.

In the organic molecular memory of the first comparative example, for example, as the distance between the first part 12a of the lower electrode 12 and the first organic molecule OM1 increases, the electrical resistance between the first part 12a of the lower electrode 12 and the first organic molecule OM1 increases. In addition, for example, as the distance between the write electrode 16 and the first organic molecule OM1 increases, the electrical resistance between the write electrode 16 and the first organic molecule OM1 increases.

Therefore, there is a concern that data write characteristics of the organic molecule OM deteriorates. Specifically, there is a concern that data may not be written to the organic molecule OM.

From the viewpoint of improving the data write characteristics of the organic molecule OM, it is desirable that the hole diameter of the memory hole 1 for forming the organic molecule layer 10 is approximately the same as the size of the organic molecule OM. However, the formation of the memory hole 1 having a small hole diameter is difficult in terms of the manufacturing process. Therefore, for example, when the memory hole 1 having a small hole diameter is formed, there is a problem that the manufacturing cost of the organic molecular memory is increased. Therefore, it is desired to improve the data write characteristics of the organic molecule OM even when the hole diameter of the memory hole 1 is large.

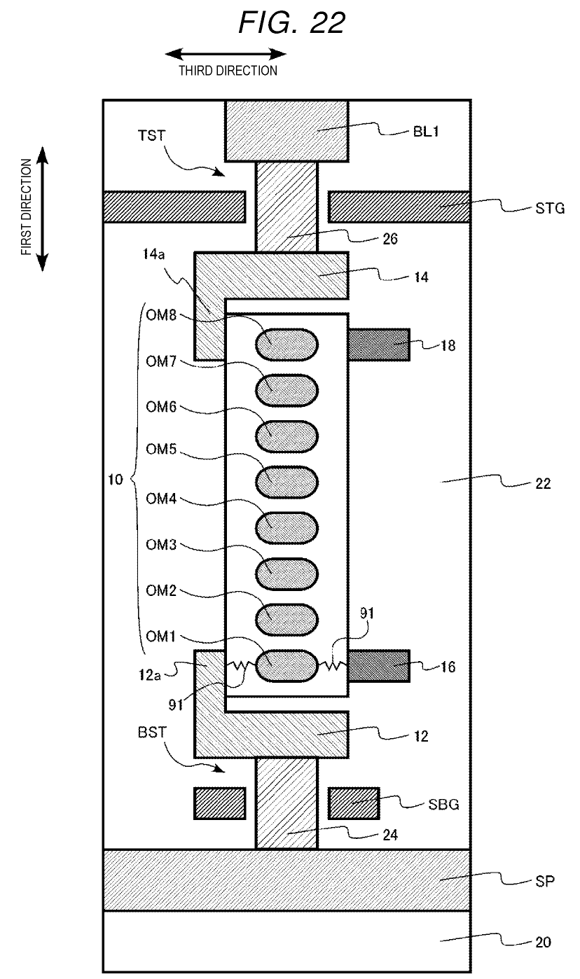

FIG. 22 is a schematic cross-sectional view of an organic molecular memory of a second comparative example. FIG. 22 is a cross-sectional view of the memory cell array. FIG. 22 is a view corresponding to FIG. 3 of the first embodiment.

The organic molecular memory of the second comparative example is different from the organic molecular memory 100 of the first embodiment in that an alkyl chain 91 is provided instead of the conductive polymer 11.

In the organic molecular memory of the second comparative example, the alkyl chain 91 is provided between the first part 12a and the first organic molecule OM1. In addition, the alkyl chain 91 is provided between the write electrode 16 and the first organic molecule OM1.

A current flows through the alkyl chain 91 by tunneling via a molecular orbital. Therefore, in the organic molecular memory of the second comparative example, the electrical resistance between the organic molecule OM and the electrode is lower than that in the organic molecular memory of the first comparative example, and the data write characteristics of the organic molecular memory of the second comparative example are improved as compared with the organic molecular memory of the first comparative example.

A tunneling probability in the alkyl chain 91 becomes exponentially low with respect to the distance. Therefore, when the distance between the organic molecule OM and the electrode is large, there is a concern that the data write characteristics of the organic molecule OM deteriorate even in the organic molecular memory of the second comparative example.

In addition, in a case where the alkyl chain 91 is chemically bonded to the electrode, there is also a problem that the choice of the material of the electrode is limited and the manufacturing of the organic molecular memory is difficult.

In the organic molecular memory 100 of the first embodiment, the conductive polymer 11 having a low electrical resistance is provided between the first part 12a and the first organic molecule OM1. In addition, the conductive polymer 11 having a low electrical resistance is provided between the write electrode 16 and the first organic molecule OM1.

Therefore, the electrical resistance between the first organic molecule OM1 and the first part 12a and the electrical resistance between the first organic molecule OM1 and the write electrode 16 are reduced, and the data write characteristics of the first organic molecule OM1 are improved. According to the organic molecular memory 100 of the first embodiment, the data write characteristics of the organic molecule OM may be improved even in a case where the size of the memory hole 1 is larger than the size of the organic molecule OM. Therefore, the memory hole 1 having a small size is not required, and the manufacturing of the organic molecular memory is facilitated.

By using the electrochemical polymerization method, the conductive polymer 11 chemically bonded to the electrode may be easily formed. In addition, the use of the electrochemical polymerization method expands the choice of the material of the electrode. Therefore, the manufacturing of the organic molecular memory is facilitated.

### First Modification Example

An organic molecular memory of a first modification example of the first embodiment is different from the organic molecular memory of the first embodiment in that the conductive polymer is provided at a position between the second part of the second electrode and the second molecule or a position between the fourth electrode and the second molecule, or both.

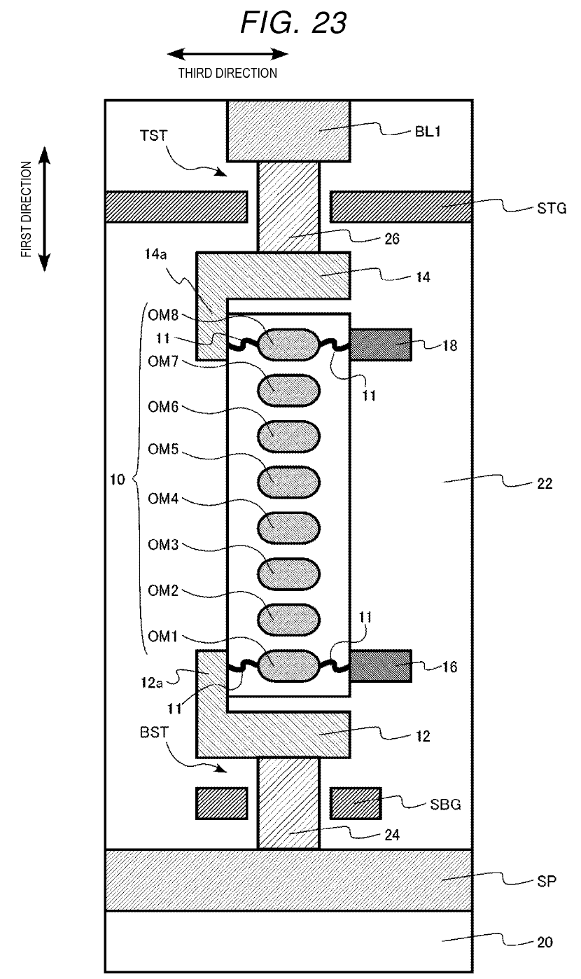

FIG. 23 is a schematic cross-sectional view of the organic molecular memory of the first modification example of the first embodiment. FIG. 23 is a view corresponding to FIG. 3 of the first embodiment.

In the organic molecular memory of the first modification example of the first embodiment, the conductive polymer 11 having a low electrical resistance is provided between the second part 14a of the upper electrode 14 and the eighth organic molecule OM8. In addition, the conductive polymer 11 having a low electrical resistance is provided between the read electrode 18 and the eighth organic molecule OM8. Therefore, according to the organic molecular memory of the first modification example of the first embodiment, the electrical resistance between the eighth organic molecule OM8 and the second part 14a, and between the eighth organic molecule OM8 and the read electrode 18 is reduced, and the data read characteristics from the eighth organic molecule OM8 may be improved.

### Second Modification Example

An organic molecular memory of a second modification example of the first embodiment is different from the organic molecular memory of the first embodiment in that the conductive polymer is not provided between the first part 12a and the first organic molecule OM1.

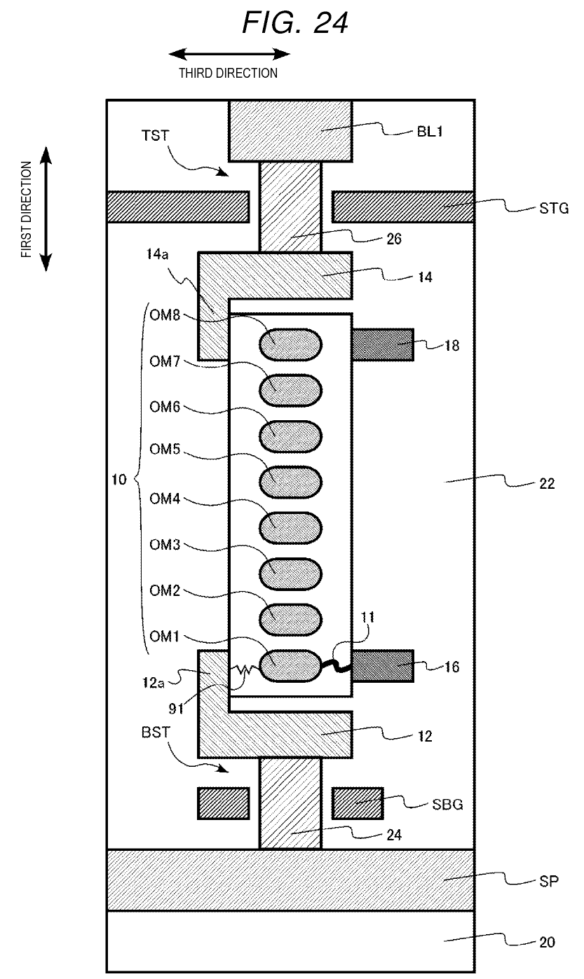

FIG. 24 is a schematic cross-sectional view of the organic molecular memory of the second modification example of the first embodiment. FIG. 24 is a view corresponding to FIG. 3 of the first embodiment.

In the organic molecular memory of the second modification example of the first embodiment, the alkyl chain 91 is provided between the first part 12a and the first organic molecule OM1. The conductive polymer 11 having a low electrical resistance is provided between the write electrode 16 and the first organic molecule OM1. According to the organic molecular memory of the second modification example, the electrical resistance between the first organic molecule OM1 and the write electrode 16 is reduced, and the data write characteristics of the first organic molecule OM1 are improved. Alternatively, the conductive polymer 11 having a low electrical resistance may be provided between the first part 12a and the first organic molecule OM1, and the alkyl chain 91 may be provided between the write electrode 16 and the first organic molecule OM1. The polarity of the applied voltage when the data 1 is written to the first organic molecule OM1 may be appropriately changed according to the type of the charge, and for example, in a case where the charge is an electron, the third voltage V3 may be higher than the first voltage V1. In this case as well, the electrical resistance between the first organic molecule OM1 and the first part 12a is reduced, and the data write characteristic of the first organic molecule OM1 is improved.

### Third Modification Example

An organic molecular memory of a third modification example of the first embodiment is different from the organic molecular memory of the first embodiment in that the conductive polymer is not provided between the first part 12a and the first organic molecule OM1. In addition, the organic molecular memory of the third modification example of the first embodiment is different from the organic molecular memory of the second modification example of the first embodiment in that the alkyl chain is not provided between the first part 12a and the first organic molecule OM1.

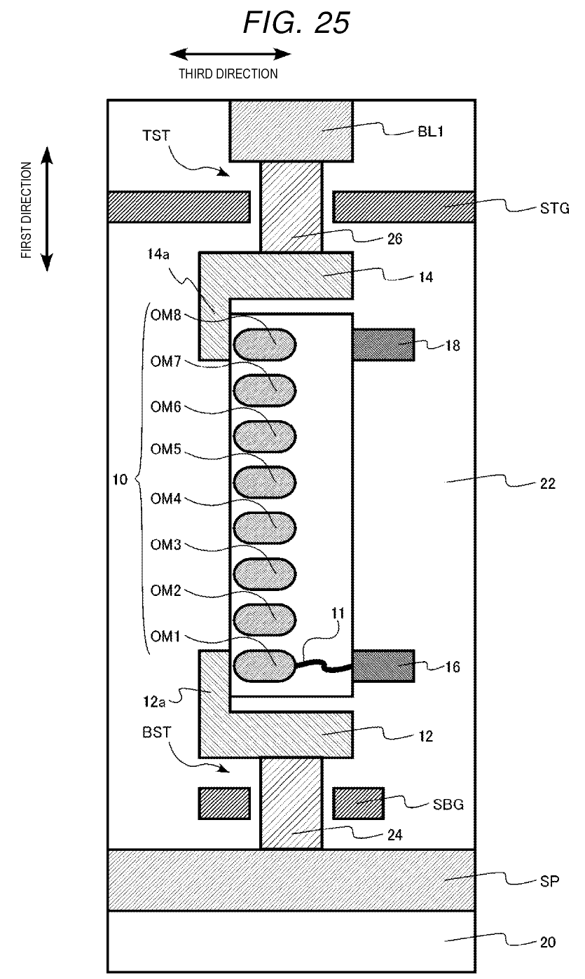

FIG. 25 is a schematic cross-sectional view of the organic molecular memory of the third modification example of the first embodiment. FIG. 25 is a view corresponding to FIG. 3 of the first embodiment.

In the organic molecular memory according to the third modification example of the first embodiment, the conductive polymer 11 having a low electrical resistance is provided between the write electrode 16 and the first organic molecule OM1. According to the organic molecular memory of the third modification example, the electrical resistance between the first organic molecule OM1 and the write electrode 16 is reduced, and the data write characteristics of the first organic molecule OM1 are improved. Alternatively, the conductive polymer 11 having a low electrical resistance may be provided between the first part 12a and the first organic molecule OM1, and the alkyl chain 91 may not be provided between the write electrode 16 and the first organic molecule OM1. The polarity of the applied voltage when the data 1 is written to the first organic molecule OM1 may be appropriately changed according to the type of the charge, and for example, in a case where the charge is an electron, the third voltage V3 may be higher than the first voltage V1. In this case as well, the electrical resistance between the first organic molecule OM1 and the first part 12a is reduced, and the data write characteristic of the first organic molecule OM1 is improved.

### Fourth Modification Example

An organic molecular memory of a fourth modification example of the first embodiment is different from the organic molecular memory of the first embodiment in that the fourth electrode is not provided.

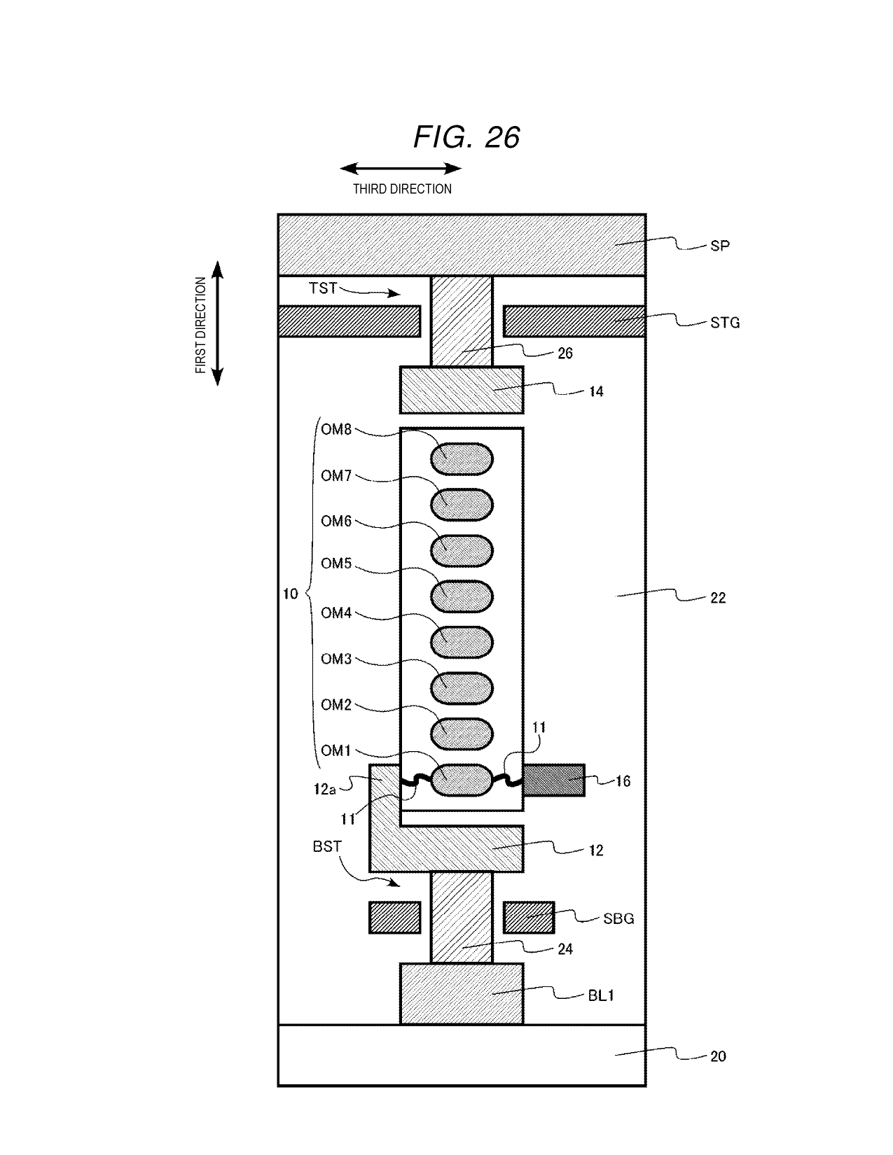

FIG. 26 is a schematic cross-sectional view of the organic molecular memory of the fourth modification example of the first embodiment. FIG. 26 is a view corresponding to FIG. 3 of the first embodiment.

The organic molecular memory of the fourth modification example of the first embodiment does not include the read electrode 18. Further, the locations of the source plate SP and the first bit line BL1 are switched. The substrate insulating layer 20 may have a configuration in which the upper and lower sides are reversed. In the organic molecular memory of the fourth modification example of the first embodiment, the write electrode 16 also serves as the read electrode 18.

In the operation of the organic molecular memory according to the fourth modification example of the first embodiment, for example, as in the operation of the organic molecular memory 100 of the first embodiment, by repeating writing the data to the first organic molecule OM1 and transmission of the data of the organic molecule OM, the data 0 or the data 1 may be stored in all the organic molecules OM. Thereafter, the write electrode 16 is made to function as the read electrode 18, and the data of the first organic molecule OM1 is read by using the lower electrode 12 and the write electrode 16.

Thereafter, for example, the first voltage V1 is set to the shift voltage Vshift, and the second voltage V2 is set to 0 V, and the data of the organic molecules OM is transmitted in a direction from the upper electrode 14 to the lower electrode 12. By repeating reading of the data from the first organic molecule OM1 and the transmission of the data of the organic molecules OM, the data of all the organic molecules OM may be read.

According to the organic molecular memory of the fourth modification example, the data write characteristics of the first organic molecule OM1 and the data read characteristics of the first organic molecule OM1 are improved.

As described above, according to the first embodiment and modification examples thereof, the organic molecular memory capable of achieving high capacity and improving data write characteristics may be achieved.

### Second Embodiment

An organic molecular memory of a second embodiment includes a first electrode; a second electrode; a third electrode; and an organic molecule layer provided between the first electrode and the second electrode, extending in a first direction from the first electrode toward the second electrode, and including a first molecule and a second molecule provided between the first molecule and the second electrode. The third electrode faces the first molecule, and the first molecule and the second molecule are cyclic compounds which have a central skeleton containing a metal element, where the cyclic compound is a naphthalocyanine, an anthrocyanine, a tetralocyanine, or a pentlocyanine, and the metal element is one metal element selected from a group consisting of manganese (Mn), iron (Fe), cobalt (Co), nickel (Ni), copper (Cu), and zinc (Zn). The organic molecular memory of the second embodiment is different from the organic molecular memory of the first embodiment in that the organic molecular memory of the second embodiment does not include the conductive polymer. Hereinafter, duplicate content with respect to the first embodiment may not be described in full.

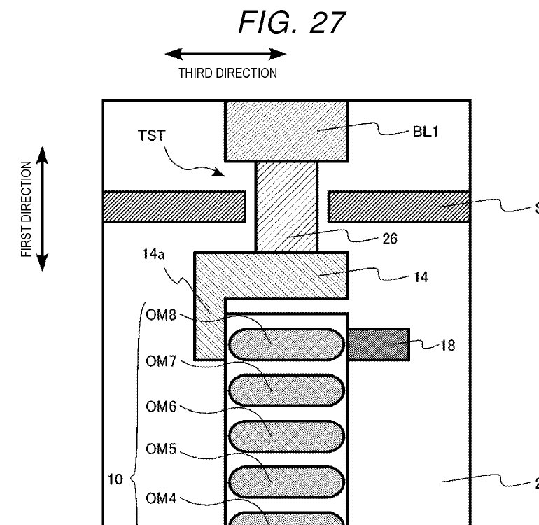

FIG. 27 is a schematic cross-sectional view of the organic molecular memory of the second embodiment. FIG. 27 is a cross-sectional view of the memory cell array. FIG. 27 is a cross-sectional view parallel to the first direction and the third direction. FIG. 27 is a view corresponding to FIG. 3 of the first embodiment.

The memory cell array 101 includes the organic molecule layer 10, the lower electrode 12, the upper electrode 14, the write electrode 16, the read electrode 18, the substrate insulating layer 20, the interlayer insulating layer 22, the source plate SP, the first bit line BL1, the lower select gate transistor BST, and the upper select gate transistor TST.

The lower electrode 12 is an example of a first electrode. The upper electrode 14 is an example of a second electrode. The write electrode 16 is an example of a third electrode. The read electrode 18 is an example of the third electrode.

The organic molecule layer 10 includes the first organic molecule OM1, the second organic molecule OM2, the third organic molecule OM3, the fourth organic molecule OM4, the fifth organic molecule OM5, the sixth organic molecule OM6, the seventh organic molecule OM7, and the eighth organic molecule OM8.

The first organic molecule OM1 is an example of the first molecule. The eighth organic molecule OM8 is an example of the second molecule.

Hereinafter, the first organic molecule OM1, the second organic molecule OM2, the third organic molecule OM3, the fourth organic molecule OM4, the fifth organic molecule OM5, the sixth organic molecule OM6, the seventh organic molecule OM7, and the eighth organic molecule OM8 may be individually or collectively referred to as the organic molecule OM.

For example, a distance between the first part 12a of the lower electrode and the first organic molecule OM1 is smaller than half of a length of the first organic molecule OM1 in the third direction. For example, the distance between the first part 12a and the first organic molecule OM1 is smaller than the disposition pitch of the organic molecules OM in the first direction.

For example, a distance between the write electrode 16 and the first organic molecule OM1 is smaller than half of a length of the first organic molecule OM1 in the third direction. For example, the distance between the write electrode 16 and the first organic molecule OM1 is smaller than the disposition pitch of the organic molecules OM in the first direction.

For example, a distance between the second part 14a of the upper electrode 14 and the eighth organic molecule OM8 is smaller than half of a length of the eighth organic molecule OM8 in the third direction. For example, the distance between the second part 14a and the eighth organic molecule OM8 is smaller than the disposition pitch of the organic molecules OM in the first direction.

For example, the distance between the read electrode 18 and the eighth organic molecule OM8 is smaller than half of the length of the eighth organic molecule OM8 in the third direction. For example, the distance between the read electrode 18 and the eighth organic molecule OM8 is smaller than the disposition pitch of the organic molecules OM in the first direction.

The organic molecule OM is a cyclic compound which has the central skeleton containing a metal element, and the cyclic compound is a naphthalocyanine, an anthrocyanine, a tetralocyanine, or a pentlocyanine. The metal element is one metal element selected from a group consisting of manganese (Mn), iron (Fe), cobalt (Co), nickel (Ni), copper (Cu), and zinc (Zn).

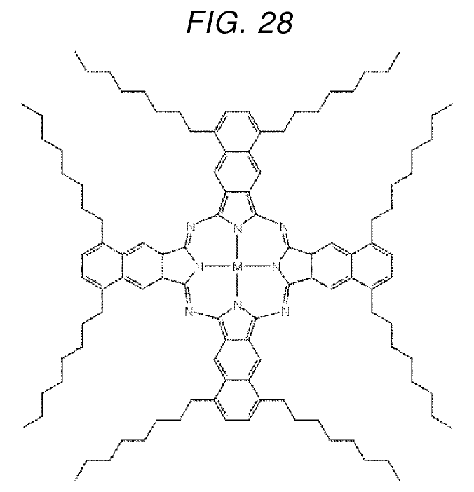

FIGS. 28, 29, 30, and 31 are diagrams showing examples of the organic molecule of the second embodiment.

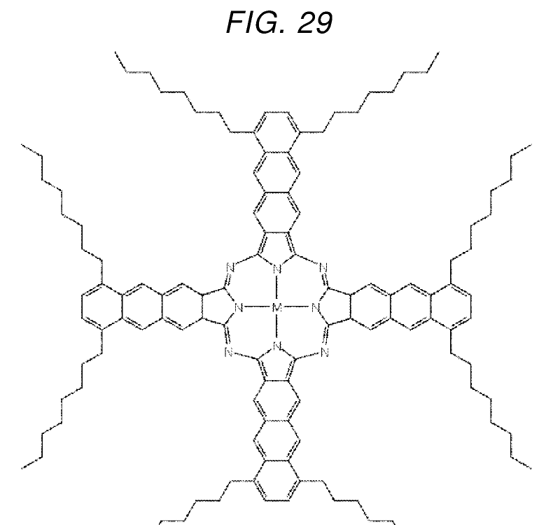

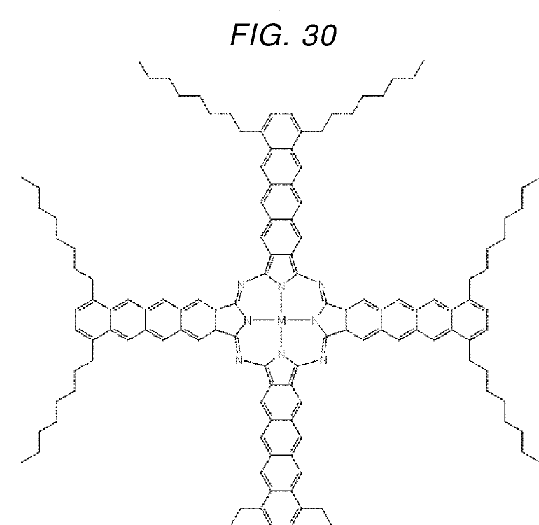

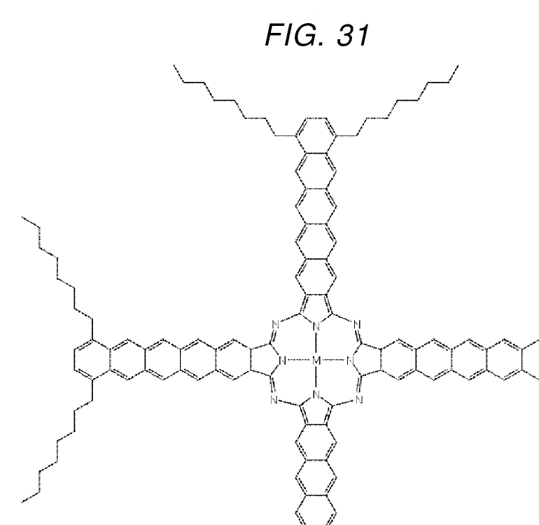

FIG. 28 is a structural formula of the organic molecule in which the central skeleton is a naphthalocyanine containing a metal element (M). FIG. 29 is a structural formula of the organic molecule in which the central skeleton is an anthrocyanine containing the metal element (M). FIG. 30 is a structural formula of the organic molecule in which the central skeleton is a tetralocyanine containing the metal element (M). FIG. 31 is a structural formula of the organic molecule in which the central skeleton is a pentlocyanine containing the metal element (M).

The metal element (M) shown in FIGS. 28 to 31 is one metal element selected from a group consisting of manganese (Mn), iron (Fe), cobalt (Co), nickel (Ni), copper (Cu), and zinc (Zn).

The organic molecules shown in FIGS. 28 to 31 include an alkyl chain having three or more carbon atoms as a side chain.

The organic molecule OM contains an alkyl chain having three or more carbon atoms as a side chain. For example, the alkyl chain of the organic molecule OM is chemically bonded to the first part 12a of the lower electrode. In addition, for example, the alkyl chain of the organic molecule OM is chemically bonded to the write electrode 16.

Next, an action and an effect of the organic molecular memory of the second embodiment will be described.

The organic molecule OM of the second embodiment is a cyclic compound in which a central skeleton contains a metal element, the cyclic compound is a naphthalocyanine, an anthrocyanine, a tetralocyanine, or a pentlocyanine, and the metal element is one metal element selected from a group consisting of manganese (Mn), iron (Fe), cobalt (Co), nickel (Ni), copper (Cu), and zinc (Zn).

According to the examination using the molecular simulation of the inventor, it is revealed that the organic molecule OM of the second embodiment has a degenerate energy level and the energy level between the first LUMO level and the second LUMO level is low.

The organic molecule OM of the second embodiment may store three or more charges at the same energy level by including the degenerate energy level. Therefore, the organic molecular memory including the organic molecule OM of the second embodiment functions as a multivalued memory capable of storing multivalued data in one memory cell.

The organic molecule OM of the second embodiment may further reduce the shift voltage Vshift when transmitting the data stored in the organic molecule OM, because the energy level of the first LUMO level and the second LUMO level is low. When transmitting the data stored in the organic molecule OM, the shift voltage Vshift is set to a voltage at which the energy levels of the first LUMO level and the second LUMO level match between the adjacent organic molecules OM. Therefore, since the energy levels of the first LUMO level and the second LUMO level are low, the shift voltage Vshift may be reduced. The organic molecular memory including the organic molecule OM of the second embodiment may reduce the shift voltage Vshift, and thereby, for example, low power consumption may be achieved.

The organic molecular memory including the organic molecule OM of the second embodiment may achieve both multivaluation of the memory cell and low power consumption.

From the viewpoint of functioning as a multivalued memory, it is preferable that the organic molecule OM has a particularly large degeneracy and is a naphthalocyanine containing manganese (Mn), a tetralocyanine containing nickel (Ni), a tetralocyanine containing copper (Cu), a tetralocyanine containing zinc (Zn), a pentlocyanine containing copper (Cu), or a pentlocyanine containing zinc (Zn).

In addition, from the viewpoint of achieving low power consumption, it is preferable that the central skeleton of the organic molecule OM has energy levels of a first LUMO level and a second LUMO level that are particularly low and is an anthrocyanine containing manganese (Mn), a tetralocyanine containing manganese (Mn), a pentlocyanine containing manganese (Mn), a tetralocyanine containing cobalt (Co), or a pentlocyanine containing nickel (Ni).

In the second embodiment as well, as one modification example, the structure may be configured without the fourth electrode as in the fourth modification example of the first embodiment.

As described above, according to the second embodiment, it is possible to achieve a multivaluation and low power consumption of a memory cell, and it is possible to achieve a large capacity organic molecular memory.

While the first and second embodiments describe examples in which the number of organic molecules OM in the organic molecule layer 10 is eight, the number of organic molecules OM is not limited to eight. The number of organic molecules OM may be any number greater than or equal to two.

While the first and second embodiments describe an example in which the number of memory strings MS is four, the number of memory strings MS is not limited to four. The number of memory strings MS may be any number greater than or equal to one.

While the first and second embodiments describe an example in which the charges stored in the organic molecule OM are electrons, the charges stored in the organic molecule OM may be holes.

In the first and second embodiments, the case where the conductive polymer 11 is always provided between the lower electrode 12 and the write electrode 16 has been described as an example, but the conductive polymer 11 may be provided only between the upper electrode 14 and the read electrode 18.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. An organic molecular memory comprising:
a first electrode including a first part;
a second electrode;
a third electrode;
an organic molecule layer provided between the first electrode and the second electrode, extending in a first direction from the first electrode toward the second electrode, and including a first molecule and a second molecule provided between the first molecule and the second electrode; and
a conductive polymer, wherein
the first molecule is provided between the first part and the third electrode in a direction intersecting the first direction, and
the conductive polymer is provided at one of a position between the first part and the first molecule and a position between the third electrode and the first molecule.

2. The organic molecular memory according to claim 1, wherein the conductive polymer is provided at the position between the first part and the first molecule and at the position between the third electrode and the first molecule.

3. The organic molecular memory according to claim 1, further comprising:
a fourth electrode,
wherein the second electrode includes a second part,
the second molecule is provided between the second part and the fourth electrode in a direction intersecting the first direction, and
the conductive polymer is provided at one of a position between the second part and the second molecule and a position between the fourth electrode and the second molecule.

4. The organic molecular memory according to claim 3, wherein the conductive polymer is provided at the position between the second part and the second molecule and at the position between the fourth electrode and the second molecule.

5. The organic molecular memory according to claim 1, wherein the conductive polymer is chemically bonded to the first part or the third electrode.

6. The organic molecular memory according to claim 1, wherein the conductive polymer is a polythiophene obtained by polymerizing a thiophene derivative, an oligothiophene obtained by polymerizing a thiophene derivative, a polypyrrole obtained by polymerizing a pyrrole derivative, an oligopyrrole obtained by polymerizing a pyrrole derivative, a polyisothianaphthene obtained by polymerizing an isothianaphthene derivative, an oligoisothianaphthene obtained by polymerizing an isothianaphthene derivative, a polyfuran obtained by polymerizing a furan derivative, an oligofuran obtained by polymerizing a furan derivative, a polyaniline obtained by polymerizing an aniline derivative, an oligoaniline obtained by polymerizing an aniline derivative, a polyvinylcarbazole obtained by polymerizing a vinylcarbazole derivative, or an oligovinylcarbazole obtained by polymerizing a vinylcarbazole derivative.

7. The organic molecular memory according to claim 1, wherein the first molecule and the second molecule are each a liquid crystal molecule.

8. The organic molecular memory according to claim 1, wherein the first molecule and the second molecule each contain a fullerene derivative.

9. The organic molecular memory according to claim 1, wherein
the first molecule and the second molecule are each a cyclic compound, which has a central skeleton containing a metal element,
the cyclic compound is a metallocene, a porphyrin, or a phthalocyanine, and
the metal element is one metal element selected from a group consisting of iron (Fe), copper (Cu), cobalt (Co), titanium (Ti), nickel (Ni), zinc (Zn), and chromium (Cr).

10. The organic molecular memory according to claim 1, wherein
the first molecule and the second molecule are each a cyclic compound, which has a central skeleton containing a metal element,
the cyclic compound is a naphthalocyanine, an anthrocyanine, a tetralocyanine, or a pentlocyanine, and
the metal element is one metal element selected from a group consisting of manganese (Mn), iron (Fe), cobalt (Co), nickel (Ni), copper (Cu), and zinc (Zn).

11. The organic molecular memory according to claim 1, wherein the organic molecule layer further includes a third molecule provided between the first molecule and the second molecule, and a fourth molecule provided between the third molecule and the second molecule.

12. The organic molecular memory according to claim 1, wherein a distance between the first part and the third electrode is two times or more a length of the first molecule in a direction from the first part toward the third electrode.

13. An organic molecular memory comprising:
a first memory string extending in a first direction;
a second memory string extending in the first direction;
a third memory string extending in the first direction;
a first wire extending in a second direction intersecting the first direction, and electrically connected to the first memory string and the second memory string in the first direction; and
a second wire extending in the second direction, electrically separated from the first wire, and electrically connected to the third memory string in the first direction, wherein each of the first memory string, the second memory string, and the third memory string includes:
a first electrode including a first part,
a second electrode provided between the first electrode and the first wire or between the first electrode and the second wire,
a third electrode,
an organic molecule layer provided between the first electrode and the second electrode, extending in the first direction, and including a first molecule and a second molecule provided between the first molecule and the second electrode, and
a conductive polymer, wherein
the first molecule is provided between the first part and the third electrode in a direction intersecting the first direction, and
the conductive polymer is provided at one of a position between the first part and the first molecule and a position between the third electrode and the first molecule.

14. The organic molecular memory according to claim 13, wherein the conductive polymer is provided at the position between the first part and the first molecule and at the position between the third electrode and the first molecule.

15. The organic molecular memory according to claim 13,
wherein each of the first memory string, the second memory string, and the third memory string further includes a fourth electrode,
the second electrode includes a second part,
the second molecule is provided between the second part and the fourth electrode in a direction intersecting the first direction, and
the conductive polymer is provided at one of a position between the second part and the second molecule and a position between the fourth electrode and the second molecule.

16. The organic molecular memory according to claim 15, wherein the conductive polymer is provided at the position between the second part and the second molecule and at the position between the fourth electrode and the second molecule.

17. An organic molecular memory comprising:
a first electrode;
a second electrode;
a third electrode; and
an organic molecule layer provided between the first electrode and the second electrode, extending in a first direction from the first electrode toward the second electrode, and including a first molecule and a second molecule provided between the first molecule and the second electrode, wherein
the third electrode faces the first molecule,
the first molecule and the second molecule are each a cyclic compound, which has a central skeleton containing a metal element,
the cyclic compound is a naphthalocyanine, an anthrocyanine, a tetralocyanine, or a pentlocyanine, and
the metal element is one metal element selected from a group consisting of manganese (Mn), iron (Fe), cobalt (Co), nickel (Ni), copper (Cu), and zinc (Zn).

18. The organic molecular memory according to claim 17, further comprising:
a fourth electrode facing the second molecule.

19. The organic molecular memory according to claim 17, wherein the first molecule and the second molecule each have a central skeleton that is a naphthalocyanine containing manganese (Mn), a tetralocyanine containing nickel (Ni), a tetralocyanine containing copper (Cu), a tetralocyanine containing zinc (Zn), a pentlocyanine containing copper (Cu), or a pentlocyanine containing zinc (Zn).

20. The organic molecular memory according to claim 17, wherein the first molecule and the second molecule each have a central skeleton that is an anthrocyanine containing manganese (Mn), a tetralocyanine containing manganese (Mn), a pentlocyanine containing manganese (Mn), a tetralocyanine containing cobalt (Co), or a pentlocyanine containing nickel (Ni).

21. The organic molecular memory according to claim 17, wherein the first molecule and the second molecule each contain an alkyl chain having three or more carbon atoms as a side chain.
